(19) United States
(12) Patent Application Publication
(10) Pub. No.: US 2007/0138644 A1
(43) Pub. Date: Jun. 21, 2007

(54) Structure and method of making capped chip having discrete article assembled into vertical interconnect

(75) Inventors: Bruce M. McWilliams, San Jose, CA (US); Giles Humpston, Aylesbury (GB); Belgacem Haba, Saratoga, CA (US); Robert Burtzlaff, Santa Clara, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/300,900

(22) Filed: Dec. 15, 2005

(51) Int. Cl. H01L 23/48

(52) U.S. Cl. 257/774

(57) ABSTRACT

A capped chip is provided which includes a chip having a front surface, a plurality of conductive features exposed at the front surface and a cap. The cap has an inner surface facing the front surface of the chip, an outer surface opposite the inner surface, and a through hole extending from the outer surface to the inner surface. A conductive interconnect extends at least partially through the through hole. The interconnect includes a conductive article which occupies a substantial portion of a volume of the interconnect and the interconnect further includes a flowable conductive medium which joins the conductive article to at least one of the plurality of conductive features of the chip or to the cap.

This application is a continuation-in-part of U.S. patent application Ser. No. 10/949,575, filed Sep. 24, 2004, which is hereby incorporated herein by reference. Said application claims the benefit of the filing dates of U.S. Provisional Patent Application Nos. 60/506,500 filed Sep. 26, 2003, 60/515,615 filed Oct. 29, 2003, 60/532,341 filed Dec. 23, 2003, 60/568,041 filed May 4, 2004, 60/574,523 filed May 26, 2004, and is a continuation-in-part of U.S. patent application Ser. No. 10/928,839 filed Aug. 27, 2004. All of said applications are incorporated herein by reference. In addition, the following U.S. Patent Applications and U.S. Provisional Patent Applications are also incorporated herein by reference: Ser. No. 11/121,434, filed May 4, 2005, Ser. No. 10/711,945, filed Oct. 14, 2004, Ser. No. 11/120,711, filed May 3, 2005, Ser. No. 11/068,830, filed Mar. 1, 2005, Ser. No. 11/068,831, filed Mar. 1, 2005, Ser. No. 11/016,034, filed Dec. 17, 2004, Ser. No. 11/284,289, filed Nov. 21, 2005, Ser. No. 10/977,515, filed Oct. 29, 2004, Ser. No. 11/025,440, filed Dec. 29, 2004, Ser. No. 11/204,680, filed Aug. 16, 2005, 60/664,129, filed Mar. 22, 2005, 60/707,813, filed Aug. 12, 2005, 60/732,679, filed Nov. 2, 2005, and 60/736,195, filed Nov. 14, 2005.

### BACKGROUND OF THE INVENTION

The present invention relates to microelectronic packaging. Microelectronic chips typically are thin, flat bodies with oppositely facing, generally planar front and rear surfaces and with edges extending between these surfaces. Chips generally have contacts on the front surface, which are electrically connected to the circuits within the chip. Certain chips require a protective element, referred to herein as a cap or lid, covering all or part of the front surface. For example, chips referred to as surface acoustic wave or “SAW” chips incorporate acoustically-active regions on their front surfaces, which must be protected from physical and chemical damage by a cap. Microelectromechanical or “MEMS” chips include microscopic electromechanical devices, e.g., acoustic transducers such as microphones, which must be covered by a cap. The caps used for MEMS and SAW chips must enclose an open gas-filled or vacuum void over the active region of the chip and beneath the cap so that the cap does not touch the acoustical or mechanical elements. Certain electro-optical chips such as optical sensing chips and light-emitting chips have photosensitive elements which also must be protected by a cap or lid. Voltage controlled oscillators (VCOs) sometimes also require a cap to be placed over the active area.

Miniature SAW devices can be made in the form of a wafer which incorporates an acoustically active material such as lithium niobate or lithium tantalate. The wafer is treated to form a large number of SAW devices, and typically is also provided with electrically conductive contacts used to make electrical connections between the SAW device and other circuit elements. After such treatment, the wafer is severed to provide individual devices. SAW devices fabricated in wafer form can be provided with caps while still in wafer form, prior to severing. For example, as disclosed in U.S. Pat. No. 6,429,511 (“the '511 patent”), a cover wafer formed from a material such as silicon can be treated to form a large number of hollow projections and then bonded to the top surface of the active material wafer, with the hollow projections facing toward the active wafer. After bonding, the cover wafer is polished to remove the material of the cover wafer down to the projections. This leaves the projections in place as caps on the active material wafer, and thus forms a composite wafer with the active region of each SAW device covered by a cap.

Such a composite wafer can be severed to form individual units. The units obtained by severing such a wafer can be mounted on a substrate such as a chip carrier or circuit panel and be electrically connected to conductors on the substrate as by wire-bonding the conductors to the contacts on the active wafer. However, this requires that the caps have holes of a size sufficient to accommodate the wire bonding process. This increases the area of the active wafer required to form each unit, requires additional operations and results in an assembly considerably larger than the unit itself.

In another alternative disclosed by the '511 patent, terminals can be formed on the top surfaces of the caps and be electrically connected to the contacts on the active wafer prior to severing the wafer into individual chips. For example, metallic vias are formed in the cover wafer prior to assembly. However, formation of terminals on the caps and vias for connecting the terminals to the contacts on the active wafer requires a relatively complex series of steps.

Similar problems occur in providing terminals for MEMS devices. For these and other reasons, further improvements in processes and structures for packaging SAW, MEMS, electro-optical and other capped devices would be desirable.

### SUMMARY OF THE INVENTION

As used herein in relation to a cap and cap wafer and a lid and lid wafer, the terms “top surface” and “outer surface” refer to an outer exterior-facing surface of the cap, and the terms “bottom surface” or “inner surface” refer to an inner, inwardly-facing surface of the cap, referring to the manner in which the cap is joined to the chip. Stated another way, the outer surface of the cap faces away from the front, i.e., the contact-bearing surface of the chip, while the inner surface of the cap faces towards the front or contact-bearing surface of the chip. The outer surface of the cap is referred to as the top surface, and the inner surface of the cap is referred to as the bottom surface, even if the capped chip structure including both chip and cap is turned over and mounted, such that the top surface faces downwardly and is joined to another article, such as a circuit panel.

In accordance with one aspect of the invention, a capped chip includes a chip having a front surface with a plurality of conductive features exposed at that front surface. The cap has an inner surface facing the front surface of the chip, an outer surface opposite the inner surface, and a through hole extending from the outer surface to the inner surface. A conductive interconnect extends from one of the conductive features of the chip at least partially through the through hole. The interconnect includes a conductive article which occupies a substantial portion of a volume of the interconnect and the interconnect further includes a flowable conductive medium which joins the conductive article to at least one of the conductive features of the chip or to the cap.

In accordance with a particular aspect of the invention, the flowable conductive medium is selected from the group consisting of a conductive adhesive and a fusible material.

In accordance with a particular aspect of the invention, the conductive article has a predetermined initial shape and the conductive article adapted to substantially retain the predetermined initial shape when a temperature of the conductive article is elevated to an attach temperature at which the conductive article is joined by the flowable conductive medium.

In accordance with a particular aspect of the invention, the flowable conductive medium prevents the conductive article from moving relative to the flowable conductive medium at an operational temperature of the capped chip.

In accordance with a particular aspect of the invention, the conductive article is sized to fit entirely within one of the through holes.

According to a particular aspect of the invention, the conductive features of the chip include bond pads, the inner surface of the cap further is vertically spaced from the bond pads and the conductive articles are sized to fit through the through holes from the outer surface to the inner surface to contact the bond pads.

According to one aspect of the invention, the conductive articles have rounded shape which can be substantially spherical or cylindrical and either solid or hollow, for example.

In accordance with a particular aspect of the invention, the conductive interconnect includes a plurality of the conductive articles, which can be arranged in a vertical stack, for example.

In accordance with one aspect of the invention, the conductive articles can be solid, hollow or a foam or a sponge. The conductive articles can include one or more materials selected from the group consisting of metals, ceramics, glasses or polymers. In the case of metal articles, the metal must have a melting point that exceeds the process temperature used to cause the fusible material to flow. Suitable metals for this application include aluminum, copper, nickel, molybdenum, tungsten. Desirably, the conductive articles are wetted by the fusible material. If this is not the case, such as occurs with aluminum, ceramics, glasses and polymers, the conductive articles may be provided with a surface coating including a wettable metal that fulfils this function.

According to one aspect of the invention, exterior surfaces of the conductive articles are wettable by a fusible material and the flowable conductive medium includes the fusible material, the fusible material joined to the conductive articles within the through holes. An example of particular fusible materials is solder, tin and eutectic composition, although other such materials may be suitable.

According to a particular aspect of the invention, the fusible material extends between the conductive feature and an area of the outer surface adjoining the through hole. The fusible material may fully or partially overlie the outer surface of the cap member.

According to a particular aspect of the invention, the cap consists essentially of at least one material selected from the group consisting of ceramics, metals, glasses, and semiconductor materials.

In such case, the cap preferably includes two or more layers of metal disposed on sidewalls of the through holes.

In an assembly which includes a capped chip having a plurality of conductive interconnects, conductive interconnects of the capped chip are joined to the terminals of the circuit panel.

According to a particular aspect of the invention, the flowable conductive medium is a conductive adhesive and the conductive article is sealed to the cap member by the conductive adhesive.

In a particular aspect of the invention, an assembly is provided which includes a capped chip having a plurality of conductive interconnects, in which at least individual ones of interconnects include conductive articles and a flowable conductive medium which joins the conductive articles to the through holes and/or chips. The conductive article is exposed at the outer surface of the cap and the assembly further includes an interconnection element, the interconnection element having at least one conductive contact compressed against the conductive article to conductively connect the interconnection element to the capped chip.

According to a particular aspect of the invention, the through holes of the cap are tapered to become narrower in a first direction from the outer surface towards the inner surface and to become narrower in a second direction from the inner surface towards the outer surface.

In one aspect of the invention, a wall of the through hole is oriented at an angle of about 90 degrees to the outer surface.

According to a particular aspect of the invention, the through hole is tapered, becoming uniformly smaller in a direction from the bottom surface towards the top surface.

In one aspect of the invention, the through hole is tapered, becoming uniformly smaller in a direction from the top surface towards the bottom surface.

In accordance with another aspect of the invention, a method is provided for forming a capped chip which has a plurality of conductive interconnects. In such method a cap member has an outer surface being a major surface of the cap member. The cap member has an inner surface opposite to the outer surface. The cap member is aligned to a chip having a contact-bearing surface and a plurality of contacts exposed at the contact-bearing surface in such manner that the inner surface of the cap member faces the contact-bearing surface of the chip. A plurality of loose conductive articles are provided in the through holes. A conductive material is flowed into the through holes to bond the loose conductive articles to the exposed contacts to form the conductive interconnects.

In accordance with a particular aspect of the invention, the step of flowing the conductive material includes elevating a temperature of the conductive material to a bonding temperature. In such method, the loose conductive articles are characterized by an initial shape prior to the step of flowing the conductive material, in that the loose conductive articles retain the initial shape when the temperature is elevated to the bonding temperature.

In accordance with another aspect of the invention, a method is provided of forming a capped chip. In such method, a chip is provided which has a front surface and a plurality of conductive features at the front surface. A lid having an outer surface, an inner surface opposite the outer surface and a plurality of through holes extending between the inner and outer surfaces is assembled to the chip such that the bottom surface faces the front surface of the chip and the outer surface faces away from the chip. The through holes are aligned with the conductive features of the chip and the bottom surface is vertically spaced from the front surface of the chip. Loose conductive articles are placed into the through holes in contact with at least ones of i) the conductive features or ii) the lid. Conductive interconnects are formed which have conductive paths extending from the conductive features at least partially through the through holes. In forming the conductive interconnects, a flowable conductive material is caused to flow in the through holes and conductively join the conductive articles to at least one of the plurality of conductive features or to the lid.

In a particular aspect of the invention, the flowable conductive material is caused to flow into the through holes from the top surface of the lid to contact the conductive features of the chip.

In a particular aspect of the invention, the through holes have walls wettable by the flowable conductive medium, and the flowable conductive material is joined to the walls of the through holes.

### BRIEF DESCRIPTION OF THE DRAWINGS

FIGS. 1-3D are views illustrating a capped chip and method of forming such capped chip according to an embodiment of the invention.

FIGS. 4A-4C are partial sectional views illustrating a capped chip and method of forming the capped chip, in accordance with a particular embodiment of the invention in which through holes have vertical sidewalls.

FIGS. 5A-5B are partial sectional views illustrating a capped chip and method of forming the capped chip, in accordance with a particular embodiment of the invention in which each conductive interconnect includes a plurality of conductive articles.

FIGS. 6A-6C partial sectional views illustrating a capped chip and method of forming the capped chip, in accordance with embodiments of the invention which include rod-like conductive articles.

FIG. 7A is a top-down plan view illustrating a capped chip in accordance with a particular embodiment of the invention in which redistribution and fan-out traces are provided.

FIGS. 7B-7C are sectional views illustrating a method of forming a capped chip in accordance with one embodiment of the invention in which the capped chip is wire-bonded to a circuit panel or package element.

FIGS. 8A-8B are partial sectional views illustrating a method of forming an assembly including a capped chip in accordance with one embodiment of the invention.

FIGS. 9A-9B are partial sectional views illustrating a method of forming an assembly including a capped chip in accordance with a particular embodiment of the invention.

FIGS. 10A-10B are partial sectional views illustrating a method of forming an assembly including a capped chip in accordance with one embodiment of the invention.

FIGS. 11A-11B are partial sectional views illustrating a method of forming an assembly including a capped chip in accordance with a particular embodiment of the invention.

FIGS. 12-17 are sectional views illustrating a method of forming an assembly including a capped chip in accordance with a particular embodiment of the invention.

FIG. 18 is a sectional view illustrating different types of caps and through hole structures therein, as used in a method of making capped chips in accordance with various embodiments of the invention.

FIGS. 19-21 are sectional views illustrating a method of forming capped chips in accordance with a particular embodiment of the invention.

FIGS. 22-24 are sectional views illustrating stages in fabrication of a capped chip having rod-like conductive articles, in accordance with a particular aspect of the invention.

FIG. 25 is a partial sectional view illustrating a structure of a capped chip in accordance with an embodiment of the invention.

FIG. 26 is sectional view illustrating a structure of a capped chip in accordance with a particular aspect of the invention.

### DETAILED DESCRIPTION

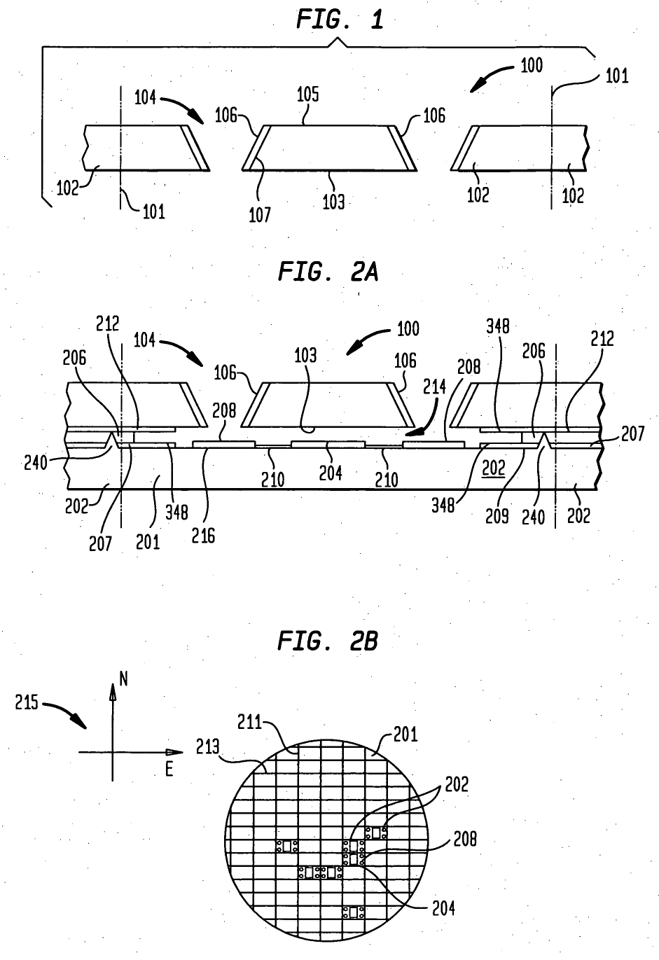

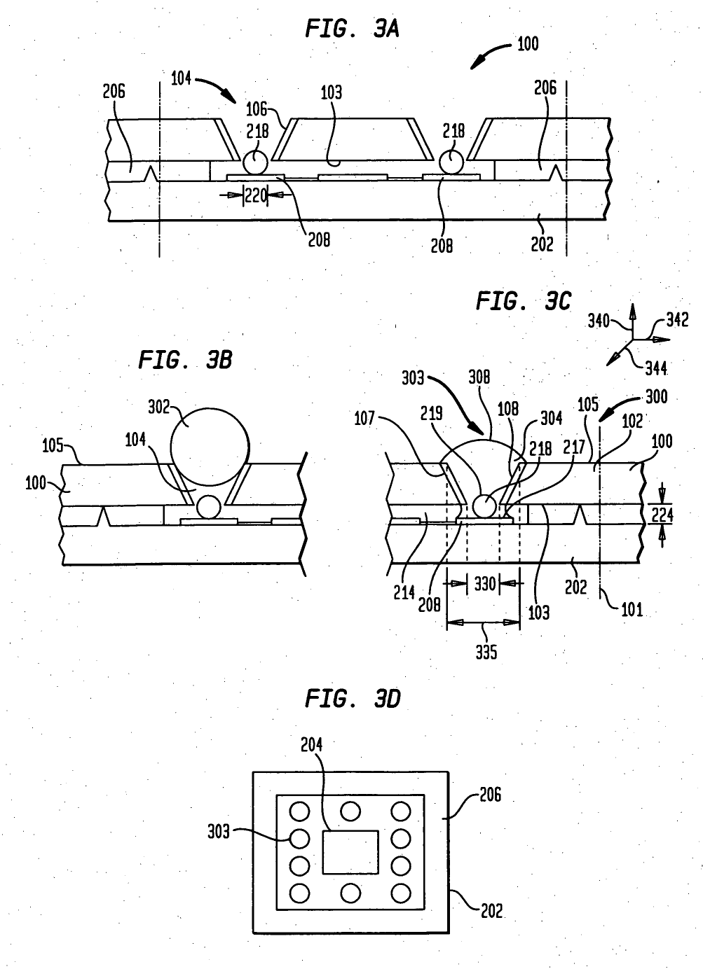

FIGS. 1-3D illustrate a capped chip and stages in a method for fabricating a capped chip according to an embodiment of the invention. In particular, FIG. 3C is a sectional view illustrating a capped chip 200 and FIG. 3D is a top-down plan view illustrating the interconnects and the seal provided on the surface of a chip included in the capped chip.

Particular types of devices, such as SAW devices and MEMs need to be sealed hermetically in order to function appropriately over the life of the device. For many silicon semiconductor devices, a package is considered to be hermitic if it has a leak rate of helium below 1×10⁻⁸ Pa m³/sec. Other devices such as electro-optical devices do not require hermeticity, but nevertheless are best packaged with a protective lid which is at least somewhat optically transmissive, the lid covering the optical device to prevent particles from reaching a surface of the electro-optical device.

Referring to FIGS. 1 and 2A, in a method of forming such capped chips, a plurality of caps 102, e.g., are attached together at boundaries 101 within a multiple cap-containing element 100 or cap wafer. The cap wafer 100 is simultaneously mounted to a plurality of chips. The chips themselves may be contained in a single wafer or a plurality of chip-containing wafers. After joining the cap wafer to the chip wafer, the chips are severed to form a unit 300, as best seen in FIG. 3C.

With continued reference to FIG. 1, the cap element 100 can be either rigid or somewhat flexible, and a variety of materials are available for its construction. In one embodiment, when the area of the cap element 100 and the chips to be joined are fairly large, the cap element 100 consists essentially of one or more materials or a composition of materials which has a coefficient of thermal expansion (hereinafter “CTE”) similar to that of the chips that are to be capped. For example, the cap element 100 may include or consist of one or more materials such as ceramics, metals, glasses and semiconductor materials. When the chips are provided on a silicon wafer or other such semiconductor wafer having a relatively low CTE, the cap element 100 preferably consists essentially of one or more CTE-matched materials such as silicon or other semiconductor material, aluminum, nickel alloys, iron and alloys of nickel and cobalt. Another suitable material having a CTE matching that of silicon is borosilicate glass.

Referring to FIG. 2A, when the device region 204 includes a SAW device, the cap element is desirably constructed of a material having a CTE which is matched to that of the SAW device. For example, when the chip includes a SAW device fabricated in a wafer including lithium tantalate material, a preferred material for the cap element is aluminum, because aluminum has a CTE which is similar to that of SAW devices. Aluminum also a low modulus of elasticity, and aluminum can be oxidized to form an insulating surface oxide of aluminum by processes such as “anodizing”. By formation of such oxide, insulating layers are formed on the top surface and bottom surface of the cap. Any openings such as through holes in the cap can also be insulated by formation of such oxide. For example, such oxide can be used to isolate respective ones of electrical interconnects which extend through such through holes.

As further shown in FIG. 1, the cap element 100 and each cap 102 thereof has a top surface 105 and a bottom surface 103. In the embodiment shown, the top and bottom surfaces define respective planes. Through holes 104 are provided in the cap element 100, generally at a rate of one or more through holes per cap 102. The through holes are formed by any technique suited for the particular material or materials of which the cap element is made. For example, when the cap element 100 is composed predominantly of silicon, metal, ceramics and glasses, the through holes can be provided by a subtractive process such as etching or drilling. Alternatively, when the cap element 100 includes a polymer, the through holes are preferably formed in a process by which the cap element is initially formed, as by molding. In the embodiment shown in FIG. 1, the cap element 100 consists predominantly of a dielectric or semiconductor material such as a glass, ceramic or a silicon wafer. Typical etching methods applied to wafers of such materials result in through holes which are tapered as shown to grow smaller from one surface towards the other surface, such that they have a substantially frusto-conical shape. In the embodiment shown in FIG. 1, the through holes are tapered to become smaller in a direction from the top surface towards the bottom surface.

As further shown in FIG. 1, bonding layers, i.e., wettable regions 106, wettable, illustratively, by a fusible medium such as solder, tin, or a eutectic composition, are provided on the sidewalls 107 of the through holes 104. The tapered profile of the through holes generally assists in permitting the wettable regions to be formed on the sidewalls 107 of the through holes 104 by deposition. Suitable bonding layers will vary with the material of the cap element and the fusible material which is used to form the bond. The particular fusible medium may affect the impedance characteristics of the bond that is formed. One exemplary bonding layer for use with a fusible medium such as a low-melting point tin-based solder and a cap element 100 consisting essentially of semiconductor, ceramic or glass, includes a 0.1 μm thick layer of titanium overlying the sidewalls of the through holes 104, an additional 0.1 μm thick layer of platinum overlying the titanium layer, and a 0.1 μm thick exposed layer of gold overlying the platinum layer.

As shown in FIG. 2A, the cap element 100 is aligned to a plurality of attached chips 202, such as contained in a device wafer 201 or portion of a device wafer. The cap element 100 is sealed to the wafer 201 by a sealing medium 206. An inner surface 103 of the cap element 100 is preferably spaced from the front surface 209 of the chip 202 so as to define a gas-filled void or vacuum void 214 between the cap element 100 and the chip 202. The device region 204 of each chip 202 is conductively connected by wiring 210 to bond pads 208 disposed in a bond pad region at the front surface 209 of each chip.

A sealing medium or sealing material 206 seals the cap element 100 to the device wafer 201. Illustratively, the sealing material 206 includes, an adhesive, a glass, especially a low-melting point glass, a fusible material such as solder, or another material which is capable of forming a diffusion bond. For example, the sealing material may be a fusible material such as solder which wets an exposed surface of a bonding element 207 and forms a strong bond thereto by diffusion of materials between the fusible material and the bonding element. The bonding element 207 is preferably a ring-like wettable metallic feature which surrounds the bond pads 208 on the front surface 209 of the chip 202. When the bonding medium is a fusible material, e.g., a solder, tin or eutectic composition, the bonding element 207 is preferably disposed in registration with a like or similar bonding element 212 provided on an inner or “bottom” surface 103 of the cap element 100. Alternatively, the sealing material can extend throughout the region occupied by the bond pads such that each conductive interconnect is individually and completely surrounded by the sealing material and the sealing material extends to the perimeter of the device region 204 of the chip. When the sealing material is a fusible material, the seal forms when the inner surface 103 of the cap element 100 and the front surface 209 of the chip containing wafer 202 are drawn together by the decreasing height of the fusible material as it cools and freezes into final form.

Alternatively, the sealing material 206 can include one or more materials such as thermoplastics, adhesives, and low melting point glasses. A low melting point glass can be used to bond the inner surface 103 of the cap element 100 directly to a front surface 209 of the wafer 201 containing chips 202, without requiring intervening metallizations such as the above-described bonding elements to be provided on opposing surfaces of the device wafer 201 and the cap element 100. In one embodiment, the device region 204 includes a SAW device, and the sealing material is disposed in an annular or ring-like pattern in a way that surrounds the bond pads 208 and the device region 204 to hermetically seal each cap 102 to each chip 202. The capped chip optionally includes a guard ring 348 which is used to prevent the sealing material from flowing beyond the wettable seal ring layer towards the device area 204 of the chip 202. The guard ring presents a surface which is not wettable by the sealing material. Certain materials present nonwettable surfaces to other materials. For example, polytetrafluoroethylene (PTFE) presents a surface to which most other materials will not adhere or wet. In one embodiment, the guard ring 348 includes PTFE as a material at the exposed surface thereof. A similar seal ring layer and guard ring are optionally provided on the inner surface 103 of the cap element 103.

Preferably, bottom surface 103 of the cap element 100 is vertically spaced from the front surface of the device wafer 201 by stand-offs 240 which protrude from the front surface of the device wafer 240. Alternatively, such stand-offs can be incorporated in the cap element 100 and protrude downward from the inner surface 103 of the cap element 100. The stand-offs 240 are used to establish and maintain a vertical spacing between the cap inner surface of the cap that is joined to each chip in order to assure that a gas-filled or vacuum void 214 overlying the device region 204 has sufficient height for device function. Stand-offs could also be separate elements distributed throughout the seal medium and contained within its thickness.

The device wafer 201 is shown in plan view in FIG. 2B. Illustratively, the wafer is one of many available types of wafers which include at least a layer of semiconductor material. Illustratively, the device wafer may include one or more semiconductors such as silicon, an alloy of silicon, another group IV semiconductor, a III-V compound semiconductors or a II-VI semiconductor. Each chip 202 includes a semiconductor device region 204 containing, for example, one or more active or passive devices formed of the semiconductor material of the chip. Examples of such devices include, but are not limited to a microelectronic or micro-electromechanical device such as a SAW device, MEMS device, voltage-controlled oscillator (“VCO”), etc., and an electro-optic device. The bond pads 208 of each chip 202 are shown in FIG. 2B. With respect to the plan view of the device wafer 201 shown in FIG. 2B which is directed towards its front surface 209, the term “vertical” means an at least generally “north-south” direction in accordance with the directions indicator 215 shown in FIG. 2B, such direction being generally within or parallel to the plane which corresponds to the major surface or “front” surface 209 of the device wafer. By contrast, the term “horizontal” means a direction within or parallel to the plane of the front surface 209 and which is transverse to the “north-south” direction. The horizontal direction is typically in an “east-west” direction according to indicator 215 and is orthogonal to the “north-south” direction. However, the east-west direction need only be a direction within or parallel to the front surface 209 which lies at an angle from the north-south direction.

With continued reference to FIG. 2B, each chip 202 is severable from other chips of the device wafer by severing the wafer along vertical dicing channels 211 and along horizontal dicing channels 213, a process known as “dicing”. In a preferred embodiment, each chip are not severed from other chips of the device wafer 201 until steps are completed by which a cap element 100 s bonded to the device wafer and conductive interconnects are formed which extend from the bond pads 208 of chips through the through holes in respective caps 102 of the cap element.

FIGS. 3A-3C are sectional views illustrating further stages in which electrically conductive interconnects 303 are formed which extend from the bond pads 208 of each chip 202 into through holes 104. As shown in FIG. 3A, an embodiment is shown in which an inner surface 103 of a cap element 100 is sealed by a sealing material 206 to the front surface 209 of a device wafer 201. In this embodiment, the bond pads 208 include solder-wettable regions which are exposed at the front surface 209 of the chip.

As particularly shown in FIG. 3A, a conductive article 218 is disposed in contact with each bond pad 208. When a conductive interconnect is later formed between the bond pad and an outer surface of the cap element, the conductive article 218 will be joined to a conductive medium which forms at least a part of the interconnect.

At this stage of processing, the conductive article is “loose”, in that it need not yet be bonded or adhere to any surface to which it is in contact. In the example shown in FIG. 3A, the conductive article has a rounded shape. More specifically, the conductive article has a spherical shape, such conductive article being referred to hereinafter as a “conductive ball”. Alternatively, the conductive article can have a shape other than rounded or spherical, provided according to other examples and embodiments of the invention herein.

As a spherical body, the conductive ball preferably substantially retains its shape at an attach temperature at which the above-described conductive medium is attached to the conductive article. Various materials and combinations of materials can be utilized to form the conductive ball. For example, the conductive ball can consist essentially of one or more metals and have either a solid core or hollow interior or foam or sponge. Preferably, the conductive ball consists essentially of one or more metals having a moderately high or higher melting point, such that the conductive ball at least substantially retains its initial shape when contacted by a fusible conductive medium at an attach temperature. For example, the conductive ball can have at least a core which consists essentially of one or more metals such as copper, aluminum, platinum and silver which melt at temperatures higher than typical fusible media such as solders, tin and eutectic mixtures. In such way, the conductive ball is avoided from melting or severely deforming during the process of being joined to the conductive medium. When the conductive ball has a solid core, it may have the same composition throughout. Alternatively, the conductive ball may be provided with an exterior coating of solder or other fusible medium to facilitate a process of joining the fusible medium to the conductive ball. In yet another variation, the conductive ball can have a hollow interior and a region overlying the interior which consists essentially of one or more metals which melts at a higher melting point than that of the fusible conductive medium used to join the conductive ball to form the conductive interconnect. In that case, as well, the hollow conductive ball can optionally be provided an exterior coating of a fusible conductive medium to facilitate the joining process.

In another variation, the conductive ball has a polymeric core, over which a cladding of a conductive material is provided. Such conductive ball is referred to herein as a “polymer core ball”. In such case, the conductive cladding preferably consists essentially of one or more metals having melting points higher than a fusible medium as described above. Such cladding is preferably wettable by the fusible conductive medium to be used. When the polymer core ball is to be joined with a fusible conductive medium, a polymer having a relatively high glass transition temperature is preferred in order to withstand the temperature at which the fusible medium is attached to the polymer core ball. However, the processes described herein are not limited to use of a fusible conductive medium for joining the conductive article. Instead, a conductive adhesive can be utilized. Since adhesives generally have attach temperatures which fall below the glass transition temperatures of most polymers, the above concerns are obviated by use of a conductive adhesive. Adhesives generally have a composition of polymers and solvents and/or precursors of polymers which combine to form polymers upon reaction, as in the case of epoxy. Adhesives can be loaded with conductive materials, e.g., a metallic conductive powder, to make them conductive, such as silver-filled epoxy, for example. In such case, the conductive article helps guide and retain the conductive adhesive where it is needed. In an embodiment as depicted in FIG. 3A, where the seal medium does not surround each individual conductive interconnect, the conductive article helps retain the conductive adhesive so that it does not bleed onto the device area of the chip.

In the example shown in FIG. 3A, each conductive ball 218 is prevented from moving relative to the bond pad 208 and possibly moving off of the bond pad 208 by the abutting surface of the exposed wall 108 of the through hole 104. As particularly shown in FIG. 3A, a region or layer 106 of a wettable material is provided at the exposed surface of the wall 108. In one embodiment, each conductive ball 218 contacts the surface 108 of the wall of the through hole and also contacts the bond pad 208 in the manner shown in FIG. 3A. Alternatively, the conductive ball 218 can contact only the surface 108 of the wall of the through hole, such as in a case where the diameter of the conductive ball 218 is larger than a width 220 of the opening of the through hole at the inner surface 103 of the cap element 100. Stated another way, the conductive ball 218 may be held somewhat above the bond pad 208 if the width 220 of the through hole at the inner surface 103 does not permit the conductive ball to fit through the opening to contact the bond pad 208. However, even in such case, a conductive ball 218 preferably has at least a portion which hangs below the inner surface 103 of the cap element but which is supported by the wall of the through hole. In such embodiment, the shape of the through hole is preferably out-of-round or oblong, in order to permit the flow of the flowable conductive medium past the conductive all to contact the bond pad below the conductive ball. In another alternative, the conductive ball 218 might contact only the bond pad 208 without touching the surface 108 of the inside wall of the through hole.

Preferably, without conducting additional processing to first join the conductive article 218 to the bond pad 208 or to an exposed surface 108 of the through hole 104, processing now proceeds by introducing a flowable conductive medium into the through hole in order to form a conductive interconnect extending from the bond pad of the chip to a point accessible from the outer surface 105 of the cap element.

In a particular embodiment shown in FIG. 3B, a mass, e.g. a ball 302 or sphere of a flowable conductive medium is provided at the opening of the through hole 104 in the top surface 105 of the cap element 100. Illustratively, the ball 302 includes a fusible conductive material such as, solder, tin or a eutectic composition. The ball 302 of fusible material is preferably placed on the cap element 100 so as to rest somewhat inside the through hole 104, as shown. When the ball 302 is a solder ball or ball of other fusible material, it can be placed at or in a through hole of the cap element by placing and aligning a screen containing holes over the cap element and allowing such balls to drop through the holes of the screen into the through holes 104 until one such ball rests in each through hole in which a conductive interconnect is to be formed. Thereafter, as shown in FIG. 3B, the ball of fusible material is heated such that the fusible material is caused to melt and flow down an exposed surface 108 within the through hole and contact the conductive ball 218.

As mentioned above, the inner surface 103 of the cap element is vertically spaced from the front surface 209 of the chip by the sealing medium and stand-offs which preferably help establish and maintain such spacing. Depending on the type of device contained in the device wafer 201 and its own particular characteristics, a small or greater vertical spacing or height 224 may be necessary between the front surface 209 of the device wafer and the inner surface 103 of the cap element. Here, the conductive ball 218 contacting the bond pad 208 and the fusible conductive medium which is flowed thereon to bond to the conductive ball, the bond pad, and/or the walls 108 of the through holes, combine to form a conductive interconnect that extends from the bond pad 208 upward at least partially through the through hole 104.

Upon contact with the conductive ball, the fusible material flows down and wets the exterior surface 219 of the conductive ball until it reaches and wets the exposed surface 217 of the bond pad 208. The wettable material provided on the exterior surface 219 of the conductive ball helps draw the fusible material downward toward the bond pad and the wettable surface 217 of the bond pad causes the fusible material to spread upon contact so as to preferably fill the space in contact with the bond pad 208 that surrounds the conductive ball 218. Thereafter, the fusible material freezes upon its temperature falling below its melting point again. Having wetted the exposed surface 108 of the wettable region within the through hole as well as the bond pad, and at least a part of the exterior surface 219 of the conductive ball 218, the solidified fusible conductive material 304 provides a conductive path extending from the bond pad 208 to an external surface 308 accessible from a top surface 105 of the cap element 100.

In the case where each individual bond pad is not totally surrounded by the seal medium, the mass 304 of fusible conductive material separates the void 214 sealed by the cap from the medium, e.g., air, or other gaseous or liquid medium which is present above the exterior surface 308 of the conductive interconnect. Thereafter, the assembly formed by the cap element 100 and the wafer 201 is severed by sawing along dicing lanes defining boundaries between individual capped chips 300, such as at boundary 101 between two such capped chips 300 shown in FIG. 3C.

One advantageous result of this process is the ability to form conductive interconnects within through holes of a capped chip by introducing a flowable conductive material into a through hole from a top surface of the cap. Moreover, this process also allows greater flexibility in setting the height 224 of the inner surface 103 of the cap above the front surface 209 of the chip 202. This is because the conductive ball has a wettable exterior surface 219, rests at least partially within the through hole 104 and either rests on the bond pad 208 or is disposed in close proximity thereto above the bond pad. These features provide a path for the fusible conductive material to flow down along the exterior surface of the conductive ball and to thereby bridge what might otherwise be an insurmountable gap between the inner surface of the cap 100 and the chip 202, given the width 220 of the through hole 104 at the inner surface 103 and the volume of fusible conductive material that is involved.

The top-down plan view of FIG. 3D further illustrates features on the surface of the chip 202 as completed in an assembly including a capped chip, the illustrated features including the device area 204 of the chip 202, the interconnects 303 which are joined to bond pads of the chip, and a ring seal 206 which is disposed as an annular “ring” or preferably square-shaped “picture-frame ring” structure that surrounds the bond pads and the device area 204 of the chip 202.

Optionally, various stages of the above-described processing can be performed in different facilities because the required cleanroom level, i.e., a level specifying the maximum concentration of contaminating particles in the air and on surfaces of the facility, varies during the stages of processing. Moreover, some of the stages of processing are best performed in facilities which are oriented to performing certain steps of processing. In a preferred embodiment, testing is performed on the results of intermediate stages of processing to eliminate product and materials from the process stream which the testing determines to be defective.

Thus, with respect to the processes described in the foregoing, a facility can fabricate cap elements, e.g. cap wafers having dimensions sized to fit the chip-containing device wafers to be covered thereby. As an example, such cap elements are fabricated from blank wafers, which can be either new wafers or possibly wafers recycled from previous processing. The cap elements are subjected to processing to form the through holes, which are then tested to assure conformance to standards of quality, e.g., placement, location, alignment, pitch, depth, sidewall angle, etc., and any of several other criteria for assuring quality. In either the same facility or a different facility, processing may then proceed with the formation of wettable regions disposed on sidewalls of the through holes, e.g., regions having one or more metallic layers referred to as “under bump metallizations” (“UBMs”) having an exposed outer surface adapted to be wetted by solder or other fusible material. Because of the techniques used, and the increased sizes of features of the cap element, and tolerances therefor, these particular steps can be performed in facilities which need not be geared to the fabrication of semiconductor devices. However, there is no constraint against performing such steps in a semiconductor fabrication facility, if desired. At the conclusion of this processing, testing is optionally performed to assure that the wettable regions of the cap element meet quality standards.

Thereafter, the cap element and the chip-containing wafer are joined together according to processing such as described above with reference to FIG. 2A, such joining process preferably being performed in a facility having a high cleanroom level. For example, such process is desirably performed in a semiconductor fabrication facility, which can be the same facility in which the device wafer which contains the chips is made. When the chips include optically active elements such as imaging sensors, processing to complete the conductive interconnects 303 (FIG. 3C) of each cap element can be deferred until later processing, if desired, since the primary concern is to mount the cap element as a cover over the chip wafer to avoid dust contamination. However, if the chip contains a SAW device, MEMs device or other such device requiring hermetic packaging, it is desirable to form the conductive interconnects 303 when the cap is first joined to the device wafer, to form a seal which protects the SAW device during subsequent stages of processing. Again, some testing is then desirably performed to assure that quality standards are met prior to proceeding to subsequent stages of fabrication. In chips that do not require hermetic sealing, subsequent processing can be conducted later to form the electrical interconnects and to provide any further sealing that is needed. Such processing can be performed in another facility other than the semiconductor fabrication facility, and at a cleanroom level that is not required to be as high as that of a semiconductor fabrication facility.

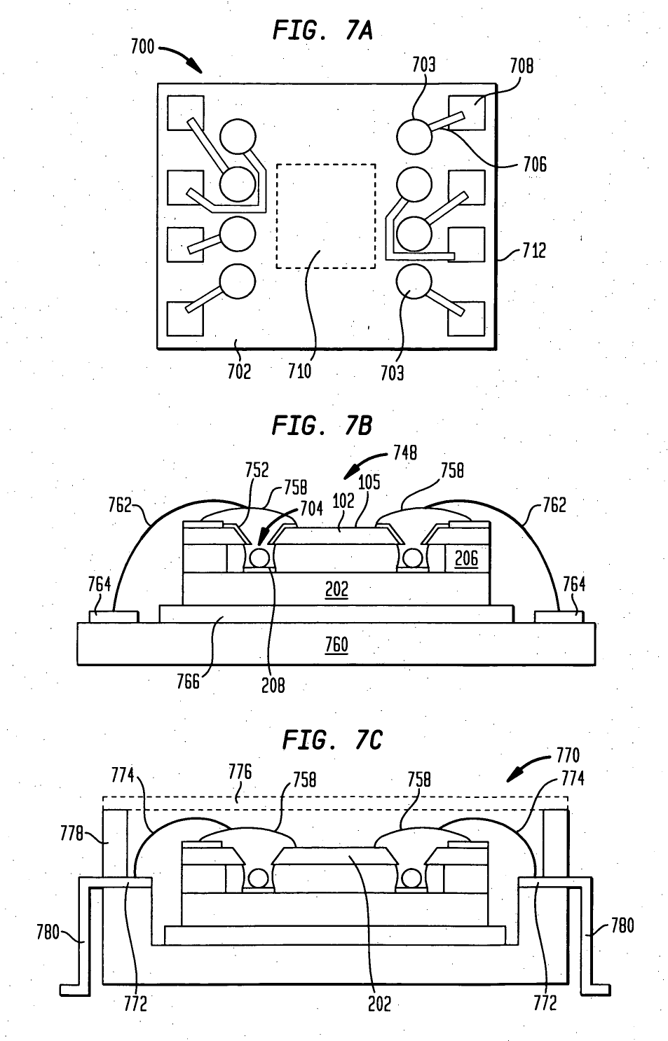

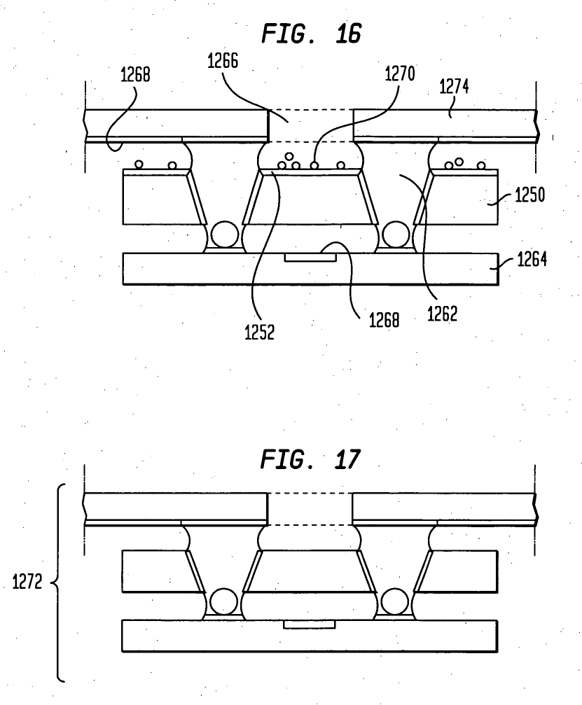

Similarly, subsequent processing to complete the packaging, as by adding other elements, e.g., optical lenses, interposer elements, thermally conductive elements and the like, and processing to mount the packaged chip to a circuit panel, such as any of the several processes described below with reference to FIGS. 7B-11B, or FIGS. 16-17, for example, need not be performed in the same facility. Such subsequent processing can be performed in environments which do not have the same cleanroom level as that in which the cap element is mounted to the chip-containing wafer, that step preferably being performed in the semiconductor fabrication facility.

The mounting of a cap element to a chip wafer, as described in the foregoing, is especially advantageous for the packaging of certain types of chips, especially those including SAW devices, MEMs devices, and optical devices, potentially resulting in increased yields, due to the ability of such processing to be performed efficiently in cleanroom environments of semiconductor fabrication facilities, where sources of contamination are kept to a minimum. In particular, it is especially desirable to protect chips which include imaging sensors such as charge-coupled device (CCD) arrays and CMOS PN arrays and the like from dust or other particle contamination by attaching a cap or lid to the front surface of the chip, as early in the packaging process as possible. Such imaging sensors include an imaging device array of a chip, over which a layer including an array of bubble-shaped microlenses is formed in contact with the device array. The array of microlenses typically includes one microlens per pixel unit of the device array, the pixel unit having dimensions of a few microns on each side. In addition, such microlenses are often made of a sticky material to which dust tends to adhere after manufacture. An example of a material used to fabricate microlenses is paralyene. Particles and dust, if allowed to settle directly on an imaging sensor, can obscure a portion of the pixel area of the imaging sensor, causing the image captured by the sensor to exhibit a black spot or degraded image.

However, owing to the shape of the microlenses and their number, and the sticky nature of the material used to make them, it is virtually impossible to remove dust or other particles that settle on the surface of a typical imaging sensor having such microlenses. Thus, any particles which settle on the imaging sensor at any time after the microlens array is formed, such as during the packaging or dicing processes, render the imaging sensor defective, such that it must be discarded. This provides an explanation why such imaging sensor chips, when packaged according to conventional chip-on-board techniques, exhibit a yield rate in the final packaged chips, which is only 80% to 85% of the chips fabricated on each wafer that initially test good.

On the other hand, particles and dust which settle on a transparent cap or cover above the outer surface of the chip do not obscure a portion of the image because the outer surface of the cap lies outside of the focal plane of the device. At worst, particles settling on the cover result in slightly decreased light intensity striking a portion of the imaging sensor. The slightly decreased light intensity rarely affects the quality of the image captured by the imaging sensor. Moreover, as described herein, the caps or covers can be mounted over the imaging sensors of the chips while the chips remain attached in wafer form, i.e., before the wafer is diced into individual chips. The mounting of the caps is preferably performed in substantially the same level of cleanroom environment as that used to fabricate the wafer, e.g., before the chip wafer leaves the semiconductor fabrication facility. In such manner, dust and particles are prevented from ever reaching the surface of imaging sensors of the chips. Moreover, once the chips are protected by such transparent caps, it becomes possible to clean the top surfaces of the covers if particles such as dust reach them. This is because the transparent caps can be made substantially planar, unlike the topography of the bubble-shaped microlenses of the imaging sensor, and are typically made of a material such as glass, which is readily cleaned by a solvent. Because the potential for direct dust contamination of the imaging sensor is virtually eliminated once the transparent cap wafer is mounted to the chip wafer, it is estimated that imaging sensor chips which are provided with transparent covers early in the packaging cycle have a yield rate of 97%-99%. In such case, the defect rate becomes no longer primarily due to contamination of the imaging sensors, but rather, for other reasons such as electrical functionality.

Desirably, wafer-level testing is performed on the chip-containing wafer 201 (FIG. 3C) prior to the cap element 100 being joined to the wafer 201 and the conductive interconnects 304 formed thereto. “Wafer-level testing” refers to such testing as is generally performed on chips, prior to the chips being severed into individual chips. More extensive testing, commonly referred to as “chip-level testing”, is typically performed only after the chip has been severed from the wafer and packaged as an individual chip.

Wafer-level testing typically tests for basic functionality, such as for electrical continuity, and basic functional operation of each chip. Such testing is desirably performed prior to individually packaging each chip, in order to eliminate the costs of packaging chips that are later determined to be defective. Thus, it is desirable to perform steps to complete the packaging of chips only with respect to chips which have passed initial wafer-level testing, i.e., “known good dies”. By completing the packaging only as to “known good dies”, unnecessary packaging operations and/or rework of packaging operations are avoided.

Wafer-level testing generally takes much less time, perhaps as much as 100 times smaller amount of time per chip tested than chip-level testing. However, the cost per chip of wafer-level testing performed by equipment capable of mechanically probing the surface of the wafer can equal or exceed that of the cost of chip-level testing, despite the greater amount of time per chip needed to perform chip-level testing. The special equipment required to precisely mechanically probe the contacts on the wafer surface is very expensive. For that reason, such special equipment is typically also subject to resource constraints within the manufacturing facility. Moreover, fewer contacts per chips are capable of being simultaneously contacted by such equipment than is generally the case for chip-level testing, for which chips are generally placed in sockets for testing. Another factor that affects the cost of wafer-level testing is that the special equipment used to probe the contacts of the wafer is limited to testing a single chip at a time, to at most a few chips at one time.

On the other hand, chips that are processed into capped chips in wafer form or lidded chips in wafer form, as described herein, e.g., in FIGS. 1-3D, are capable of being tested at the wafer level, with test equipment that is potentially less expensive than the mechanical probing equipment described above, because interconnects of the chips are disposed on the top surface of the cap wafer and for that reason, are capable of being probed by equipment similar to that used to perform chip-level testing. For example, the top or outer surface of the cap wafer can be mechanically contacted by a contact-bearing dielectric element of test equipment, the contacts of the test equipment being held in contact with the conductive interconnects of multiple chips of the wafer, as by mechanical force. In such manner, testing is performed through voltages and/or currents applied through the interconnects 303 of each capped chip 300 to a plurality of the chips which remain attached in form of the wafer 201 (FIG. 3C). In that way, a plurality of chips of each wafer are simultaneously tested and determined to be good or defective, using equipment that can be less expensive than the above-described test equipment, because the need to mechanically probe the wafer surface directly is eliminated. In a particular embodiment, a greater subset of tests than is generally performed as “wafer-level testing” is performed to the capped chips. This is possible because the wafer containing the capped chips is able to be tested by test equipment that is less expensive than the mechanical probing equipment discussed above. In addition, the ability to test a greater number of the chips at one time permits more testing to be performed per chip for the same total amount of test time using the less expensive test equipment. In a highly preferred embodiment, the capped chips are tested in such equipment for all or nearly all of the same functions ordinarily performed during chip-level testing, prior to the chips being severed from the capped chip-containing wafer into individual capped chips.

One feature of the embodiments described above with reference to FIGS. 1-3D is the use of through holes which are uniformly tapered to become progressively smaller with depth from the top surface of the cap element 100. It is preferable for through holes to be tapered this way in many instances to assist in channeling the flowable conductive medium downward towards the chip. The variation between the diameter of the through hole at the top surface 105 relative to the diameter at the bottom surface 103 assists initially in maintaining the solder ball 302 (FIG. 3B) (being somewhat larger than the smaller diameter 330 of the through hole) in place inside the through hole 104. Referring to FIG. 3C, the through holes of the cap 102 are tapered to become smaller in a direction from the top surface 105 of the cap downward towards the bottom surface 103. From the perspective of the top surface 105 a sidewall 107 of each through hole is angled inwardly at an angle typically ranging from about 5 degrees to 70 degrees from the vertical, the vertical being a direction 340 which is normal to directions 342, 344 parallel to the top surface 105. More preferably, the angle of the sidewall 107 to the vertical is between 10 degrees and 60 degrees and, most preferably, between 20 degrees and 60 degrees. In each case shown in FIG. 3C, the diameter of each through hole varies between a larger diameter 335 at the top surface 105 and a smaller diameter 330 at the bottom surface 103. The thickness of the cap 102 illustratively ranges between 100 and 300 μm. The smaller diameter 330 of the through holes at the bottom (inner) surface 103 is on the order of about 40 to 100 μm, and the larger diameter 335 of the through holes at the upper surface 105 of the cap element ranges from twice as large to many times larger than the smaller diameter 330.

In one embodiment of making the through holes, the cap element 100 consists essentially of silicon. Wet chemical etching is applied through openings in a patterned masking layer (not shown) at the top surface 105 to form the through holes, resulting in the sidewall 107 being angled inwardly towards the bottom surface 105 at an angle of about 60 degrees with respect to the vertical.

However, in many cases it is preferable to make the angle between the sidewall and the top surface 105 small, in order to reduce the amount of area occupied by each interconnect. In such case, laser drilling may be used to form through holes in a cap element which consists essentially of silicon, glass, ceramic or other similar material. Laser drilling typically results in through holes which are angled inwardly at an angle of about 7 degrees to the normal, as viewed from the top surface 105 downward. However, when the bond pads of a chip are closely spaced, it may be preferable for the through holes to have a profile other than that shown and described relative to FIG. 3C. When considered in terms of forming interconnects to closely spaced bond pads 208 of a chip 202, it is seen that the larger diameters 335 of the through holes at the top surface 305 of the cap element may well limit the spacing at which such interconnects 303 can be made.

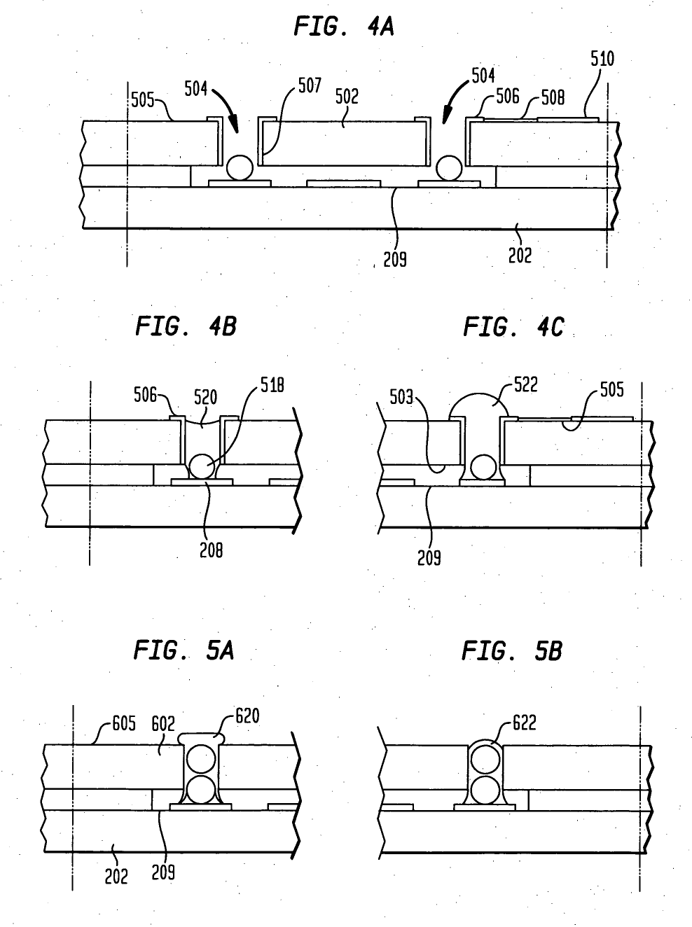

As shown in FIG. 4A, in a variation of the above-described embodiment, the walls 507 of the through holes 504 of the cap are oriented in a vertical direction with respect to the major surface 209 of the chip 202. In this way, the through holes 504 are disposed at right angles to the outer or top surface 505 of the cap 502. As in the above-described embodiment, the solder-wettable metallizations 506 are disposed on the walls 507 of the through holes, and extend onto the top surface 505. These metallizations are connected to traces 508 which, in turn, connect to contacts 510 disposed on the top surface of the cap 502.

FIG. 4B is a partial sectional view illustrating a capped chip, after a flowable conductive material 520 (e.g., fusible conductive material or conductive adhesive) has been flowed into the through hole 504 to join the conductive article 518 to the bond pad 208 and the solder-wettable metallization 506 of the cap. FIG. 4B illustrates a case in which the amount of flowable conductive material only partially fills the through hole. FIG. 4C is a partial sectional view illustrating a variation of the case shown in FIG. 4B in which the amount of flowable conductive material exceeds the available volume of the through hole and the vertical spacing between the bottom surface 503 of the cap and the front or major surface 209 of the chip. Accordingly, in this embodiment, the flowable conductive material 522 extends above the top surface 505 of the cap. In this way, a conductive interconnect has an enlarged surface to which connection can be made.

In a particular embodiment, shown in partial sectional view in FIG. 5A, a conductive interconnect is formed using a plurality of conductive balls as described above or balls of fusible conductive material, e.g., solder, inside a through hole of the cap 602 which are supported by the bond pad 208 of a chip 202. While two such balls are used to form the conductive interconnect as shown in FIG. 5A, a greater number of conductive balls may be used depending upon the diameter of the through hole and the height of the top surface 605 of the cap above the front surface 209 of the chip. FIG. 5A illustrates a case in which the flowable conductive material 620 extends above and onto the top surface 605 of the cap. FIG. 5B illustrates a variation in which the flowable conductive material 622 does not extend onto the top surface of the cap.

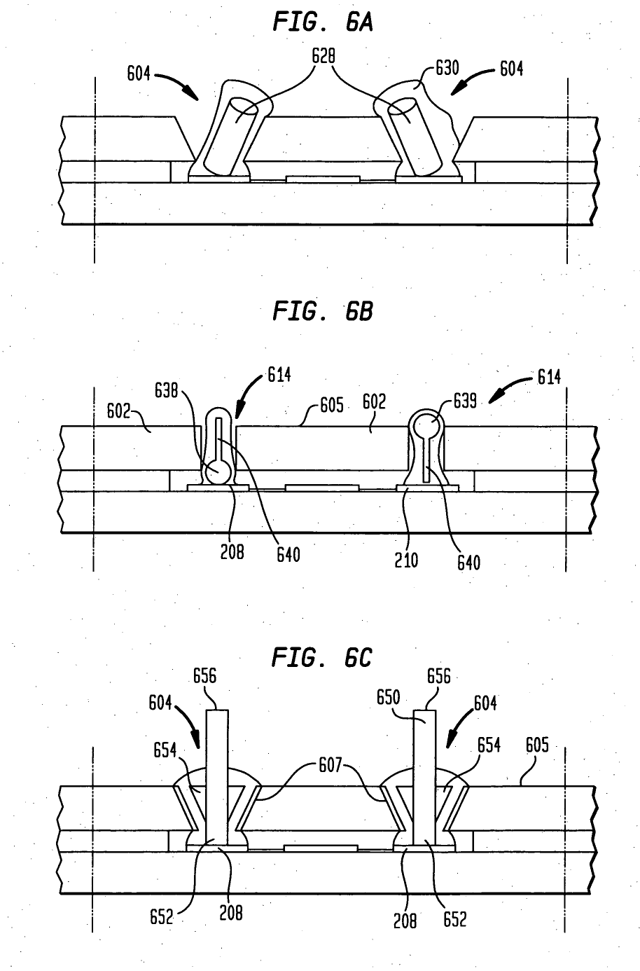

FIG. 6A is a sectional view illustrating a capped chip in accordance with another embodiment of the invention in which the conductive interconnects include cylindrical or rod-like conductive posts 628 in place of the conductive balls as in the above-described embodiment. In forming the interconnects, the conductive posts are dropped into the through holes 604 where they come to rest on bond pads 208. A flowable conductive medium is flowed into the through holes which joins the conductive posts to the bond pads. The conductive interconnects permit external connection to the capped chip at the top surface. In the particular embodiment shown the flowable conductive material is not required to bond to the walls of the through holes. Instead, the rod-like shape of the conductive articles reliably permits external interconnection to be made to the chip from points above the top surface of the cap. However, if desired, the walls of the through holes can be provided with solderable metallizations or other features wettable by the flowable conductive material.

In yet another embodiment illustrated in the FIG. 6B, the shape of the conductive articles can be made part spherical, part rod-like. In such way, the conductive articles 638, 639 fall easily into the through holes 614, owing to the center-of gravity of each conductive article resting with the spherical side of the article 638, 639. Here, as above, the rod-like extension 640 of each article helps to draw the flowable conductive material onto itself to extend the vertical and lateral dimensions of the conductive interconnect at or above the top surface 605 of the cap 602. FIG. 6B illustrates two examples: one in which the conductive article 638 is disposed with the spherical side resting on the bond pad 208 of the chip, and another example in which the conductive article 639 is disposed with the rod-like extension resting on a bond pad 210 of the chip.

In a particular embodiment illustrated in FIG. 6C, discrete conductive rods 650 either consist essentially of one or more conductive materials, e.g., a metal, or include a conductive metallic coating overlying a rod-like conductive, nonconductive, or semiconductive inner element, the conductive rods being inserted into through holes 604. Exemplary materials of which the rod-like conductive articles or inner elements thereof can be made include metals (e.g., aluminum, copper, nickel, molybolenum and tungsten), ceramics, glasses and polymers. The rod-like articles can be solid or hollow and may be in form of a foam or sponge, e.g., as a metal covered inner element of foam or as a foam metal or sponge metal element. In addition, the rod-like articles can be either rigid or compliant in nature, such that the conductive interconnects formed therefrom are able to move (pivot or bend) or compress when the top ends of the conductive interconnects contact conductive features of other microelectronic elements. The conductive rods 650 are preferably long enough to protrude a substantial distance above the top surface 605 of the cap, e.g., from 50 microns (μm) to several hundred microns while bottom ends 652 of the rods preferably rest upon the bond pads 208 of a chip of a wafer including such chips, such that the bottom ends of the rods are referenced to the face of the chip. Exterior surfaces of the rods are preferably coated with a wettable metal, such as with a first coating of nickel (preferably 3 μm in thickness) and then with a second coating of gold (preferably 0.1 μm in thickness) overlying the nickel coating. As such, the rods 650 are preferably conductively joined to and sealed to the bond pads 208 and wettable metal features 607 on walls of the through holes 604 using a fusible material which wets the rods and the walls, e.g., a material such as solder. Alternatively, the rods are joined and sealed to the bond pads and walls via an adhesive which is preferably conductive. As assembled within the through holes and conductively joined thereto, the rods facilitate conductive interconnection to the bond pads 208 and other devices, e.g., package elements or circuit panels at points well above the upper (outer) surface 605 of the cap. Thus, the rods 650 and the material which joins the rods to the bond pads of the chip, considered together, form pins of the chip, allowing conductive contact to be made to the chip at locations well above the upper or outer surface 605 of the cap.

Preferably, the shape of the rods are cylindrical in order to fit within the tapered through holes. Optionally, the rods include a tapered section 654 which is matched in contour to the taper of the through holes in which they are inserted. When present, the tapered sections 654 preferably have a frustum shapes which are centered about the central axes of the rods.

As conductively joined to the bond pads of the chip, the conductive rods provide an external pin grid array interface to the chip which extends through the cap. Such pin grid array interface renders the capped chip compatible for interconnection with further components and processing utilized for interconnecting pin grid array type chip packages. In addition, the distance which the conductive rods or “pins” extend above the top surface 605 of the cap provides a stand-off distance between the capped chip and a circuit panel (rigid or flexible), or a socket to which the capped chip is connected. Moreover, since the top ends 656 of the rods (pins) are disposed well above the cap surface 605, different materials can be used to connect the top ends of the pins to other parts or assemblies (not shown) than the material which is used to seal the through holes 604. For example, in a particular embodiment, a conductive adhesive can be used to fasten the pins within the through holes and the exposed top ends of the pins be pressed into a socket or connected to lands on a circuit panel by soldering. Further, the pins are mechanically relatively robust, such that they provide reusable contacts, allowing the pins of the capped chip to be temporarily connected or attached to a test interface for burn-in purposes and tested, then detached from the test interface and permanently attached later to a circuit panel for use.

Although a wafer level package that possesses metal or metal-coated pins protruding above the face of the cover wafer can be set into a socket for the purposes of test and burn-in, the higher cost of custom sockets makes them on the whole undesirable. Another solution which can be less expensive and less complex is to press the pins of the capped chip into contact with a circuit panel, e.g., a printed circuit board (PCB) such as a commonly used epoxy-fiberglass board which has an array of lands, each land which matches the location of each pin. However, in such arrangement, each pin can be assured to mate with its respective land only when both the ends of the pins and the lands on the PCB are perfectly co-planar. In practice, such result is unlikely to occur usually. One solution to this problem is to make the pins elastically and/or plastically compliant in the vertical direction, i.e., in a direction perpendicular to the exterior surface 605 of the cap.

In one embodiment of the invention shown in plan view in FIG. 7A, a unit 700 includes a cap 702 having a plurality of conductive interconnects 703 formed in a manner such as the conductive interconnects 303 shown and described above with respect to FIGS. 1-3D. In this embodiment, the conductive interconnects are disposed at positions close to a device region 710 of a chip. The conductive interconnects are connected by redistribution and fan-out traces 706 to a set of corresponding conductive contacts 708 disposed farther away from the device region 710. In such manner, signals coming off of the chip (not shown) are redistributed through the conductive interconnects 703 and traces 706 to the contacts 708 which lie farther from the device region 710 and closer to the peripheral edges 712 of the capped chip 700.

FIG. 7B illustrates a capped chip 748 according to one embodiment of the invention. As in the above-described embodiments, the conductive interconnects 758 of each capped chip 748 includes a conductive article such as a conductive ball which is joined to the bond pads 208 of the chip 202 and to the conductive elements of the cap including the solder-wettable metallizations 752 provided on walls of the through holes 704. Here, conductive interconnects are provided which include bonding wires 762 which extend from the conductive interconnects 758 exposed at the top surface 105 of the cap 102 or conductive contacts 708 in FIG. 7A to terminals 764 of a packaging element 760 to which the chip 202 is mounted face-up via a die attach adhesive.

In this embodiment, the cap 102 may be formed of any of the above-listed types of materials, and may be partially or fully optically transmissive, that term denoting an element which is either somewhat translucent or transparent to light in a range of wavelengths of interest. In a particular embodiment, the cap 102 is transparent, consisting essentially of a material such as a glass or a polymer, which can be molded. In a particular embodiment, the cap 102 is molded to contain an optical element, e.g., a lens, such as the caps and optical elements described in commonly assigned, co-pending U.S. patent application Ser. No. 10/928,839, filed Aug. 27, 2004, that application incorporated by reference herein. The cap may provide other functions such as selective filtering of certain wavelengths (e.g. prohibit the passage of infrared through to an optical image sensor) by either supporting coatings or incorporating within it materials that provide the same effect.

In a particular embodiment, a thermal conductor can be mounted between the chip 202 and the cap 102 for conducting heat away from the chip and onto a thermal conductor mount provided in the packaging element, such as described in commonly assigned, co-pending U.S. patent application Ser. No. 10/783,314 filed Feb. 20, 2004, the contents of which are hereby incorporated by reference herein. In a particular embodiment, the chip is bonded in a “chip-on-board” configuration) to a circuit panel, e.g., a printed circuit board or flexible circuit panel, in place of the packaging element 760.

The above-described embodiment shown in FIG. 7B can be especially advantageous for the packaging of chips which include optically active elements, for example, image sensors. Such sensors are especially vulnerable to dust or other particle contamination which is most likely to occur after the chip has been fabricated. Dust or other particles which settle directly on the imaging are of the chip can obscure a portion of the pixels of the active imaging area, thus rendering the chip unusable. The method provided in this embodiment reduces the risk of such contamination by providing a protective optically transmissive cover over the chip prior to performing subsequent higher-level packaging operations.

In another embodiment, as illustrated in FIG. 7C, bonding wires 774 extend from conductive interconnects 758 of the chip or conductive contacts 708 in FIG. 7A to conductive bonding shelves 772 which are connected to the leads 780 of a gull-wing package 770. This packaged chip preferably includes an optically active chip and an optically transmissive cover 202, such as that described above with respect to FIG. 7B. An additional package lid 776 can be mounted to vertical members 778 of the package, the package lid 776 desirably also being at least partially optically transmissive, and preferably being transparent. The gull-wing package is one of many common packages that are equally suitable for this application.

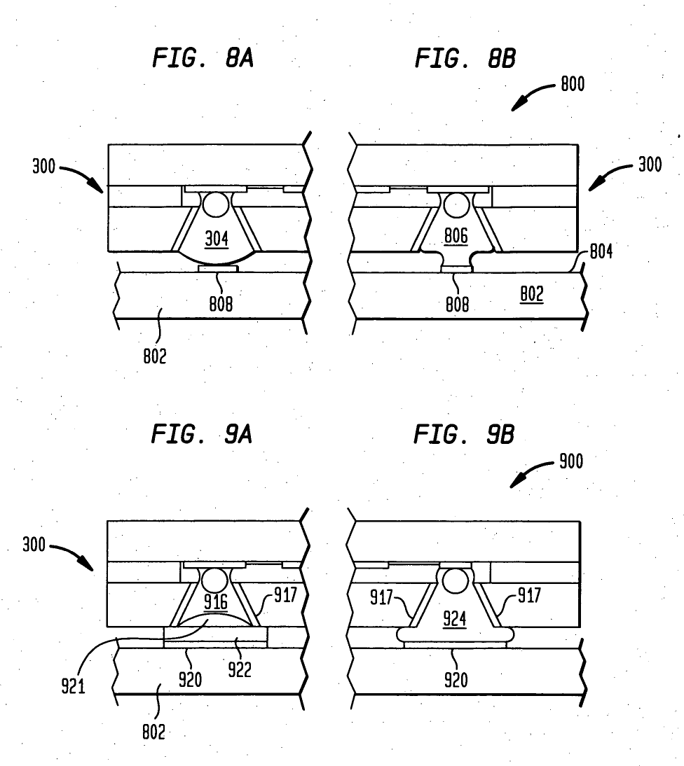

As shown in FIGS. 8A and 8B, once a unit 300 including a capped chip has been formed, it may then be aligned to and surface mounted to a printed circuit board (PCB) or other type of circuit panel 802 to form an assembly 800. FIG. 8A shows the unit 300 having the fusible material 304 of the interconnect aligned to a terminal, e.g., a land 808 of the circuit panel 802. FIG. 8B illustrates the resulting assembly 800 after heating to cause the fusible material to be bonded to the terminal 808 of the circuit panel 802. While flux is generally utilized for the purpose of joining materials in an oxygen-containing environment, the joining process can be performed fluxlessly, under conditions which inhibit contamination, i.e., by joining the unit 300 to the circuit panel 802 in the presence of a non-oxygen containing environment such as nitrogen, argon, or a vacuum, for example.

In accordance with some surface mounting practices, extra solder can be applied to the circuit panel prior to mounting the unit to increase the volume of solder available to make the connection. Such pre-forms of solder can be applied to the terminals of the circuit panel with flux, if needed, prior to mounting the unit. FIGS. 9A and 9B illustrate such technique. As illustrated in FIG. 9A, due to the process used to make the capped chip unit 300, the fusible material 916 provided on the bonding layer 917 of the through hole of the unit 300 does not completely fill the through hole, but leaves a void 921 in a portion of the through hole above the circuit panel 802. By providing a pre-form 922 of additional solder or other fusible material on the terminal 920 of the circuit panel 802, sufficient solder is provided to provide a reliable connection between the unit 300 and the circuit panel. FIG. 9B illustrates the assembly 900 formed by the unit and the circuit after heating to cause the solder contained in the pre-form and in the through hole to melt and join, being drawn into the through hole to form connection 924 to terminal 920. As a result of the added solder from the pre-form, a bulked up solder connection 924 is provided which is sufficient to establish a connection to the terminal.

As an alternative to that described above, the solder pre-form can be provided for use in hierarchically soldering the unit to the circuit panel. Stated another way, the conductive interconnects of the unit 300 can be formed using a solder or other fusible material which melts at a higher temperature than the solder used to join the unit 300 to the circuit panel, such that the original higher temperature material does not melt and reflow during the subsequent joining operation.

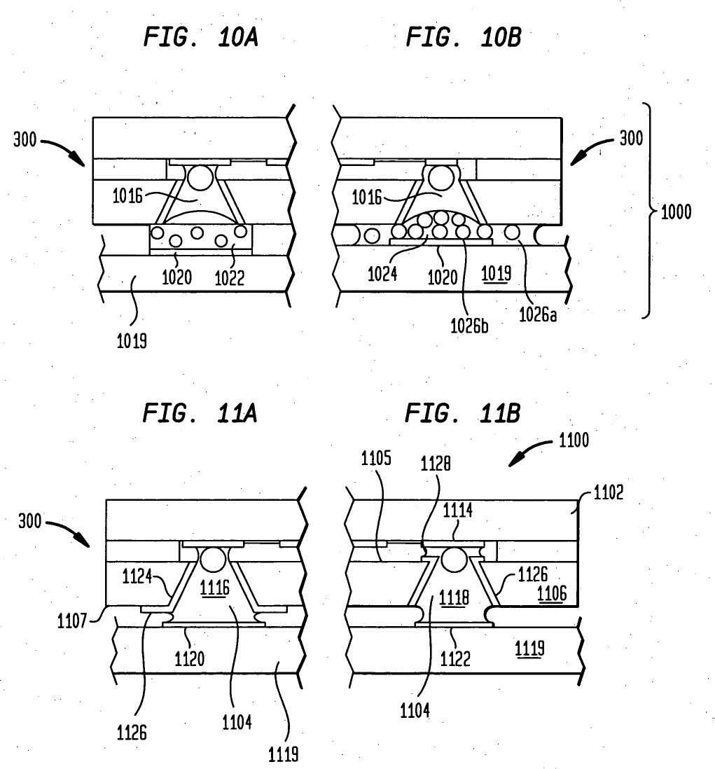

FIGS. 10A and 10B illustrate another method for joining the unit 300 to a circuit panel to form an assembly 1000, in which a conductive adhesive 1022 is used to conductively join the unit 300 to a land 1020 of the circuit panel 1019. FIG. 10A illustrates a stage after which the unit 300 has been placed in alignment with the circuit panel 1019, such that the solder 1016 in the through hole is positioned over the land 1020. FIG. 10B illustrates a subsequent stage after the unit has been pressed into contact with the land 1020, causing metal particles in the conductive adhesive to contact land 1020 and the conductive interconnects 1018. However, as also shown in FIG. 10B, a certain amount of the conductive adhesive 1024 flows off the land 1020 onto other areas of the circuit panel. For this reason, in order to avoid the making of electrical connections in places where they are not desired, the conductive adhesive is desirably an anisotropic conductive adhesive 1024, as shown in FIG. 10B. Such anisotropic conductive adhesive contains discrete conductive particles 1026, such as conductive spheres that are normally spaced from each other by a fluid medium used to carry them. When pressed between two objects at a spacing equal to the width of the sphere, the conductive spheres provide an electrical connection between the two objects. However, due to the lateral spacing between the conductive spheres, no substantial electrical connection is provided in a lateral direction which runs between the surfaces of the two objects.

FIG. 11A illustrates a variation of the embodiment shown above in which the unit 300 includes a bonding layer 1124 which extends from inside the through hole 1104 to have an extension 1126 extending on the mounting face 1107 of the unit 300. The extension 1126 is preferably provided as an annular ring surrounding the through hole 1104. The extension 1126 provides additional surface area for retaining solder 1116, prior to and after the unit 300 is bonded to the circuit panel 1119. The extension 1126 and a larger amount of solder adhering thereto on the unit 300, can mitigate against having to provide additional solder on the terminal 1120 of the circuit panel, as discussed above with respect to FIG. 10A.

FIG. 11B illustrates yet another variation in which unit 300 includes an extension 1128 of the bonding layer 1126 on the surface 1105 of the cap 1106 which faces the chip 1102. During the joining process of the cap to the chip, the extension 1128 draws solder from inside the through hole 1104 onto itself to bring it closer to the bond pad 1114 of the chip 1102. This, in turn, assists in forming the bond between the cap 1106 and the chip 1102. Again, the conductive interconnects of the unit 300 can be formed using a solder or other fusible material which melts at a higher temperature than the solder used to join the unit to the circuit panel to form the assembly 1100. In such way, the original higher temperature material will not melt or reflow during the subsequent joining operation which joins the capped chip to the circuit panel 1119.

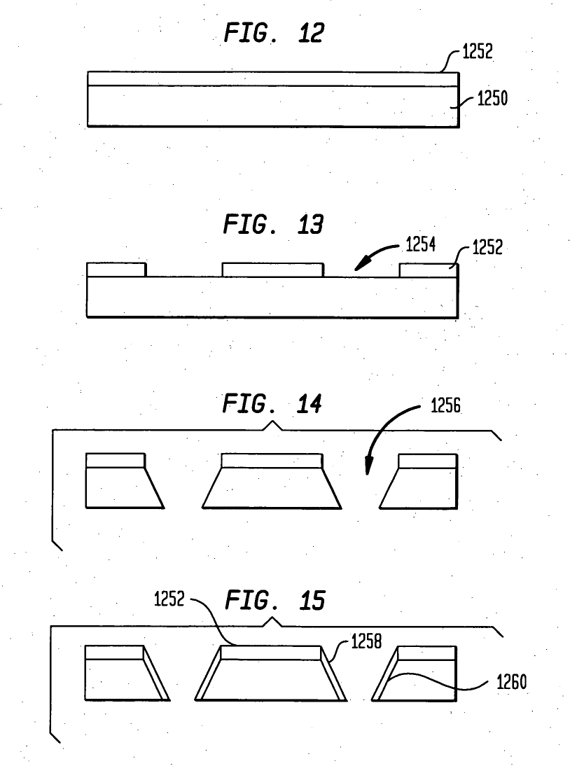

FIGS. 12-17 illustrate a particular variation of the process described above with respect to FIGS. 1-3D and 8A-8B, or one of the alternatives shown in FIGS. 9A-11B for making a unit and joining it to a circuit panel. A “lid”, like the “cap” described in the foregoing, refers to an article that is mounted as a cover over the front surface of a chip.

Some types of chips, particularly chips which include an electro-optic device, need to be packaged with a cap which is at least partially optically transmissive. The term “optically transmissive” is used to refer to a material that is either optically transparent or optically translucent in a range of wavelengths of interest, whether such wavelengths of interest are in a visible, infrared or ultraviolet range of the spectrum. For example, electro-optic imaging chips including charge-coupled device (“CCD”) arrays and CMOS PN arrays require a lid which includes an optically transmissive package window, in order to prevent dust or other particles from landing on the CCD array, which would optically impair and obscure pixels of the CCD array. Such lid can also be used to protect against damage due to corrosion by atmospheric contaminants, particularly water vapor. The lid can be of any suitable optically transmissive material, including but not limited to glass, polymer and semiconductors. After the chip is joined to the lid, a turret or train assembly containing a lens, and optionally infrared (IR) and/or ultraviolet (UV) filters is joined to the lid, e.g., as by welding, adhesive bonding or use of a fusible material such as solder.

In this variation, a sacrificial coating is applied to a surface of a lid prior to joining the lid to a chip, in order to protect the lid against contamination. The sacrificial coating is then removed later, after steps are performed to join the lid to the chip to form a unit to join that unit to a circuit panel. As above, while the process is described here in terms of joining a lid to a chip, it should also be understood, with appropriate modifications, to apply to the joining of a lid element containing multiple attached lids to a wafer or other substrate which includes multiple attached chips, after which the joined lid element and wafer are severed along dicing lanes to form individually lidded chips.

When a lid is joined to a chip by one of the above-described processes, steps to bond the lid to the chip can introduce contaminating material. Thereafter, steps to join the lidded chip to a circuit panel can introduce further contaminating material. Contamination can result from the environment in which the chip is packaged or, from the nature of the process itself that is used to perform the joining processes. For example, a joining process that involves solder with flux can produce residual material that is undesirable to leave on the surface of the cap. Other methods of bonding a lidded chips

Accordingly, as shown in FIG. 12, a sacrificial coating 1252 is applied to the surface of an optically transmissive lid 1250. The sacrificial coating 1252 is a material which can be applied and remain through the steps of bonding the lid to the chip, but then be removed to leave the surface of the lid in a clean condition without degrading the condition of the joints of the assembly. In the embodiment shown in FIG. 12, the sacrificial coating includes a photosensitive resist film, suitable for use in subsequent photolithographic patterning of the lid. Such resist film is best chosen with regard to the etchant which will be used to pattern the material of the lid, which can vary between inorganic materials such as glasses and organic materials such as polymers. For example, an etchant such as fluorosilicic acid is suitable for patterning a lid which is formed of glass, especially lids which are formed of a glass which has been doped to facilitate chemical etching such as borosilicate glass. In such case, a spin-on photoresist or hot roll laminate photoresist is suitable for use in etching of glass. Such photoresists are also not degraded by temperatures at which solders melt, nor by fluxes used in soldering processes. However, such photoresists are also readily dissolved and cleared from a surface through organic solvents.

FIG. 13 illustrates the patterned photoresist film 1252, after it has been exposed and developed to produce openings 1254 in the photoresist layer 1254. Thereafter, as shown in FIG. 14, the lid is etched, using the patterned photoresist film as a mask to produce through holes 1256.

Thereafter, as shown in FIG. 15, further steps are performed to deposit bonding layers 1258 on the sidewalls 1260 of the through holes. The bonding layers 1258 are provided for the purpose of permitting a fusible material such as solder, tin, etc. to be bonded to the through holes of the lid, in a manner as described above with respect to FIGS. 1-3D. During the deposition, a contact mask may be placed over the photoresist film 1252 as needed, to prevent the photoresist film from being sealed within the bonding material, which might interfere with its later removal depending on the type of resist. Such bonding layer is provided, for example, by deposition including electroless plating or electroless plating followed by electroplating. Alternatively, the bonding layer is provided through vapor phase deposition, i.e., any one of many deposition processes such as physical vapor deposition (PVD), chemical vapor deposition and the like.

A subsequent stage of fabrication is shown in FIG. 16, after the lid 1250 has been joined to a chip 1264 by a set of electrically conductive interconnects 1262 in a manner such as described above with respect to FIGS. 1-3D, and after the interconnects of the lidded chip have been joined to a circuit panel 1274. The circuit panel 1274 includes an opening 1266 or, alternatively, a window consisting of an optically transmissive material, disposed in alignment with the electro-optic device 1268 of the chip 1264 to provide an optically transmissive path to and from the electro-optic device 1268. The circuit panel 1274 can be of any type, being either rigid, semi-rigid, or flexible. In one embodiment, the circuit panel 1274 is flexible and has a flexible dielectric element on which conductive traces are disposed.

As also shown in FIG. 16, one result of the prior joining processes is unwanted residual matter 1270, e.g., particles, flux or adhesive residue, etc., that remains on the surface of the photoresist film 1252. As illustrated in FIG. 17, the residual matter is then removed in steps used to remove the photoresist film, such as through washing of the assembled circuit panel and the lidded chip in an organic solvent in which the film is soluble. This results in an assembly 1272 in which the contaminating material has been removed, and which is now ready for steps to provide a higher order assembly. Thereafter, a turret, train or other optical element, may be mounted above the opening 1266 in the circuit panel 1274.

The process shown and described above can be modified in several alternative ways. In one alternative process, the lid is patterned by laser drilling rather than chemical etching. The laser drilling is performed after the sacrificial coating is applied, at which time material ejected from the drilled openings collects on the sacrificial coating. Thereafter, the ejected material is prevented from contaminating the lid when the sacrificial coating is removed from the surface of the lid.

In another embodiment, the sacrificial coating need not be a photoresist film and the coating need not patterned to provide a mask for etching through holes in the lid. Rather, in such embodiment, the sacrificial coating is provided on a face of the lid, and thereafter, the lid is mounted to the chip, such as through a sealing medium or fusible conductive medium as described above. The lidded chip is then mounted to an additional element such as a circuit panel, or alternatively, a turret, or ‘train’, as described above. Thereafter, the sacrificial coating is removed, removing with it residual matter remaining from the prior steps used to mount the lid to the chip and the lidded chip to the additional element.

In a particular form of such embodiment, the sacrificial coating is one that is mechanically releasable from the surface of the lid, such as by peeling. For example, such film can be provided of an adhesively backed plastic, polymeric film capable of withstanding the processes used to join the lid to the chip and that which joins the combined unit to another element. For example, materials such as those used in the adhesive of removable self-stick notepaper and in food-wrap film appear suited for this purpose. Alternatively, the peelable film can be a metal such as molybdenum or other metal or other rigid or semi-rigid polymer.

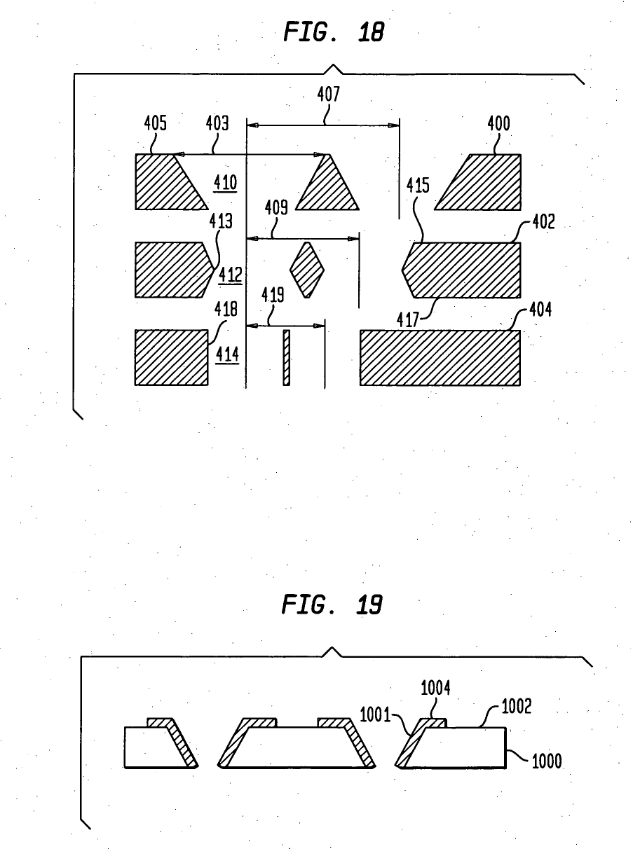

FIG. 18 illustrates three individual caps 400, 402 and 404, respectively, in which through holes 410, 412, and 414, respectively, have been patterned differently, and in which the pitch between adjacent through holes varies significantly according to the method used to pattern the caps. Thus, cap 400, having through holes 410 which are tapered from only one surface, i.e., the top surface 405, has the largest pitch 407, because of the large diameter 403 of the through holes 410 that exist at the top surface 405. Through holes are ordinarily tapered from one surface of the cap by isotropic etching from that one surface. On the other hand, cap 402 has smaller pitch 409 because its through holes are tapered from both the top surface 415 and the bottom surface 417 of the cap 402, such that the profile of the through holes includes an internal edge 413. Such taper is typically achieved by etching the through holes 412 simultaneously and isotropically from both the top and bottom surfaces of the cap 402. In some cases, depending upon the degree to which the through hole is etched in a lateral direction (being the direction parallel to the diameter 409) the internal edge 413 can acquire the appearance of a “knife edge”. Cap 404 illustrates a case in which through holes 414 are patterned without tapering, having straight, vertical sidewalls 418. The pitch 419 of through holes 414 of the cap 404 is the smallest of the pitches 407, 409, 419, because of the straight, vertical profile of the through holes 414.

However, the profiles of the through holes of cap 402 and cap 404 are such that they do not permit the same techniques to be used as described above relative to FIGS. 1 through 3D when joining the cap 402 or 404 to a chip. Regions which are wettable by a fusible conductive medium, e.g., by solder, cannot be easily formed on sidewalls of the through holes 412 of cap 404 by preferred patterning processes which include use of vapor phase deposition and wet electrochemical processes to make the tapered through holes as described above relative to FIGS. 1 through 3D. These patterning processes cannot be performed from just the top surface 415 or the bottom surface 417 of the cap, because patterning will be achieved only on surfaces that face up, i.e. only the surface of the through hole above the internal edge 413 and upward, including the top surface 415 of the cap 402. This precludes the portion of the through hole below the internal edge 413, i.e., facing towards the bottom surface 417 from being properly metallized. In the case of cap 404, the vertical, straight profile of the sidewall 418 of the through hole 414 makes it difficult to achieve a suitable metallization.

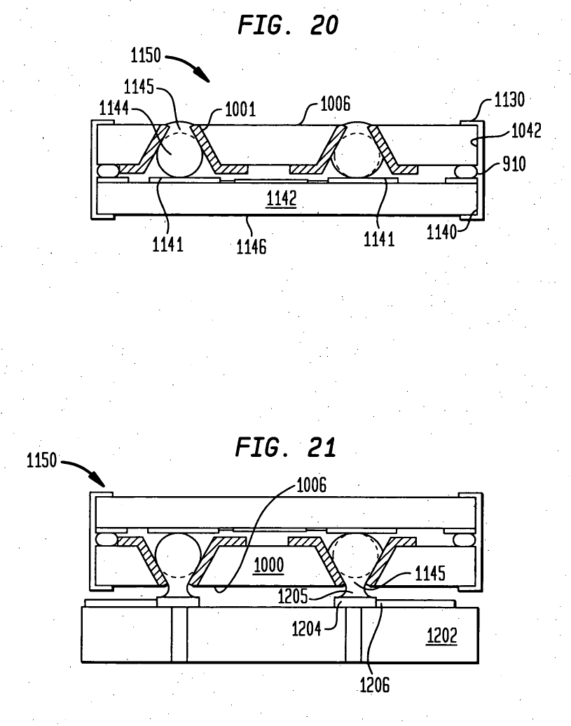

FIG. 19 illustrates an embodiment in which the bonding layer extends as an annular structure 1004 disposed on the bottom surface 1002 of a cap 1000. In this embodiment, the through holes are preferably tapered so as to become progressively smaller from the bottom surface toward the top surface. As such, the tapered through holes are substantially frusto-conical in shape. The tapering of the through holes is not absolutely necessary. In a particular embodiment, an annular structure 1004 is formed by deposition through openings of a masking layer (not shown) on the cap, the openings being wider in comparison to those used to form the metallizations shown in FIG. 1. Alternatively, the annular structure 1004 can be formed by decreasing the size of mask patterns disposed between the annular structures, when metallization patterns are formed by a subtractive process following the formation of a metallization layer over the cap. FIG. 20 illustrates a packaged chip 1150 showing a further variation in which the conductive balls 1144 are of a type which remain substantially rigid upon heating to a bonding temperature, or which have a core which remains substantially rigid. In such embodiment, the conductive balls 1144 are used to maintain a desirable vertical spacing between the cap 1000 and the chip 1142. A solder bond or diffusion bond can be used to join a metal disposed at an exterior of the conductive ball 1144 to the metallization layer 1001 of the cap 1000 and to join such metal to a bond pad 1141 of the chip, for example. Joining may also be accomplished using an electrically conductive organic material such as a conductive adhesive.

As further shown in FIG. 20, a fusible material such as solder, tin, eutectic or other flowable conductive material 1145 is provided to fill the space between the conductive ball and the top surface 1006 of the cap. In a particular embodiment, an additional seal 1130 can be provided over the peripheral edges 1042, 1140 of the cap and the chip, respectively, by depositing an additional sealing material. The additional seal 1130, which desirably also covers the already provided sealing material 910, may be provided for the purpose of achieving hermeticity, electrical isolation, or other such purpose. The additional seal also preferably extends onto the top surface 1006 of the cap and the rear surface 1146 of the chip.

FIG. 21 illustrates a further embodiment in which the packaged chip 1150 shown in FIG. 20 is mounted to a circuit panel 1202 having one or more terminals 1204 and traces 1206 disposed thereon. Illustratively, the packaged chip 1150 is mounted to the circuit panel 1202 through a solder bond between the solder or other conductive material 1145 present at the top surface 1006 of the cap 1000 and masses 1205 of solder disposed on the terminals 1204 of the circuit panel 1202.

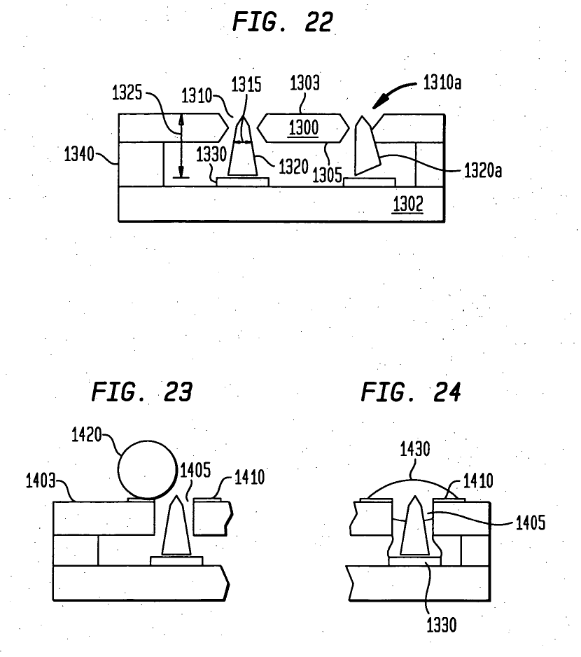

With reference to FIG. 22, another embodiment of a method of making a capped chip having vertical interconnects is shown in which the through holes 1310 of a cap 1300 are not required to have solderable bonding layers prior to the cap 1300 being joined to the chip 1302. FIG. 22 illustrates a case in which the through holes 1310 of the cap 1300 are tapered from both the top surface 1303 and the bottom surface 1305, as described above with respect to FIG. 18. In this embodiment, loose, rod-like conductive articles 1320, 1320a are disposed and attached to bond pads 1330 within through holes 1310. The rod-like conductive articles 1320 provide a surface for bonding of solder or other conductive material to form a vertical interconnect extending upwardly from a chip 1302. As described in relation to other embodiments above, a “picture frame” ring-seal 1340 seals the gap between the chip and the cap. Suitable rod-like structures include stud bumps with tails.

The rod-like conductive articles 1320, 1320a are desirably tapered, as shown in FIG. 22, as can be provided according to several processes known to those skilled in the art. In this embodiment, the conductive articles desirably have a shaft diameter 1315 which is between about 30% and 70% of the diameter of the minimum opening of the through hole. Desirably, the rod-like conductive articles 1320, 1320a protrude through the through hole to extend above the top surface 1303 of the cap. The particular article 1320a is slanted as positioned within through hole 1310a due to factors (alignment, etc.) involved in its placement within the through hole.

FIG. 23 illustrates a variation of the embodiment shown in FIG. 22, in which the through holes have a straight, vertical profile, rather than being tapered from both sides, as described above with respect to FIG. 22. As shown in FIG. 23, the top surface 1403 of the cap is optionally provided with a solderable bonding layer 1410. The bonding layer is preferably provided as an annular structure surrounding each through hole. FIGS. 23 and 24 illustrate two stages of processing. In an earlier stage of processing, shown in FIG. 23, a solder ball 1420 is disposed on the bonding layer 1410, as placed thereon by a prior solder ball stenciling process. A subsequent stage of processing, shown in FIG. 24, illustrates the reflowed solder ball 1430 as joined to the conductive article by a subsequent reflowing process. During such reflowing process, the solder ball 1430 is drawn onto the surface of the conductive article by a solder-wettable metal present at the surface of the conductive article such as gold, tin or platinum. As a result, the solder forms a continuous solid electrically conductive mass connecting the conductive article to the bond pad 1330, and to the bonding layer 1410 of the cap, sealing the cap at the through hole 1430.

In a variation of the above process, the solder ball 1420 is placed on the bonding layer 1410 of the cap 1400 and first bonded thereto to form a solder bump. Thereafter, once the rod-like conductive article is positioned within the through hole, the solder bump is reflowed by heating to flow onto the conductive article and form the interconnect.

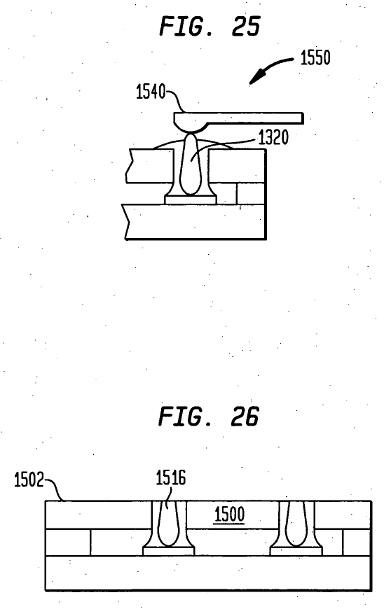

FIG. 25 illustrates a variation of the embodiment illustrated in FIG. 24 in which electrical connection to the capped chip 1550 is provided by way of a sliding or deformable mechanical contact 1540 which maintains contact to the rod-like conductive article 1320 through pressure.

FIG. 26 illustrates yet another variation, in which the rod-like conductive articles 1516, which include a solder or other conductive joining material applied thereto, are planarized to the top surface 1502 of the cap 1500, after the cap 1500 is aligned and joined to the chip. The planarized surfaces of the conductive articles 1516 and joining material thus form a land grid array for interconnection of the cap 1500 to further elements such as a circuit panel (not shown).

As these and other variations and combinations of the features discussed above can be utilized without departing from the present invention as defined by the claims, the foregoing description of the preferred embodiments should be taken by way of illustration rather than by way of limitation of the invention as defined by the claims.

1. A capped chip, comprising:
a chip having a front surface and a plurality of conductive features exposed at said front surface;
a cap having an inner surface facing said front surface of said chip, an outer surface opposite said inner surface, and a through hole extending from said outer surface to said inner surface; and
a conductive interconnect extending at least partially through said through hole, said interconnect including a conductive article occupying a substantial portion of a volume of said interconnect, said interconnect further including a flowable conductive medium joining said conductive article to at least one of said plurality of conductive features or to said cap.

2. The capped chip as claimed in claim 1, wherein said flowable conductive medium is selected from the group consisting of a conductive adhesive and a fusible material.

3. The capped chip as claimed in claim 1, wherein said conductive article has a predetermined initial shape, said conductive article is adapted to substantially retain said predetermined initial shape when a temperature of said conductive article is elevated to an attach temperature at which said conductive article is joined by said flowable conductive medium.

4. The capped chip as claimed in claim 1, wherein said flowable conductive medium prevents said conductive article from moving relative to said flowable conductive medium at an operational temperature of said capped chip.

5. A capped chip as claimed in claim 1, wherein said conductive article is sized to fit entirely within one of said through holes.

6. A capped chip as claimed in claim 1, wherein said chip has a plurality of said conductive features, said conductive features including bond pads, said inner surface of said cap further being vertically spaced from said bond pads and said conductive articles being sized to fit through said through holes from said outer surface to said inner surface to contact said bond pads.

7. A capped chip as claimed in claim 6, wherein said conductive articles have rounded shape.

8. A capped chip as claimed in claim 7, wherein said conductive articles have substantially spherical shape.

9. A capped chip as claimed in claim 7, wherein said conductive articles have substantially cylindrical shape.

10. A capped chip as claimed in claim 1, wherein said conductive interconnect includes a plurality of said conductive articles.

11. A capped chip as claimed in claim 10, wherein said plurality of conductive articles of said at least one interconnect are arranged in a vertical stack.

12. A capped chip as claimed in claim 8, wherein said conductive articles have a polymeric core and a conductive coating overlying said polymeric core.

13. A capped chip as claimed in claim 10, wherein said conductive articles have a polymeric core and a conductive coating overlying said polymeric core.

14. A capped chip as claimed in claim 8, wherein said conductive articles include one or more materials selected from the group consisting of metals, ceramics, glasses and polymers and said conductive articles have a form selected from solid, hollow, foam or sponge.

15. A capped chip as claimed in claim 1, wherein exterior surfaces of said conductive articles are wettable by a fusible material and said flowable conductive medium includes said fusible material, said fusible material joined to said conductive articles within said through holes.

16. A capped chip as claimed in claim 15, wherein said fusible material includes at least one of a solder, tin and a eutectic composition.

17. A capped chip as claimed in claim 16, wherein said fusible material extends between said conductive feature and an area of said outer surface adjoining said through hole.

18. A capped chip as claimed in claim 17, wherein said fusible material at least partially overlies said outer surface of said cap member.

19. A capped chip as claimed in claim 15, wherein said cap consists essentially of at least one material selected from the group consisting of ceramics, metals, glasses, polymers and semiconductor materials.

20. A capped chip as claimed in claim 19, further comprising two or more layers of metal disposed on sidewalls of said through holes.

21. An assembly including a capped chip as claimed in claim 1 including a plurality of said conductive interconnects, further comprising a circuit panel having a plurality of terminals, wherein said conductive interconnects are joined to said terminals of said circuit panel.

22. A capped chip as claimed in claim 1, wherein said flowable conductive medium is said conductive adhesive and said conductive article is sealed to said cap member by said conductive adhesive.

23. An assembly including a capped chip as claimed in claim 1, wherein said conductive article is exposed at said outer surface of said cap member, said assembly further comprising an interconnection element, said interconnection element having at least one conductive contact compressed against said conductive article to conductively connect said interconnection element to said capped chip.

24. A capped chip as claimed in claim 5, wherein said through holes of said cap are tapered to become narrower in a first direction from said outer surface towards said inner surface and to become narrower in a second direction from said inner surface towards said outer surface.

25. A capped chip as claimed in claim 1, wherein a wall of said through hole is oriented at an angle of about 90 degrees to said outer surface.

26. A capped chip as claimed in claim 1, wherein said through hole is tapered, becoming uniformly smaller in a direction from said bottom surface towards said top surface.

27. A capped chip as claimed in claim 1, wherein said through hole is tapered, becoming uniformly smaller in a direction from said top surface towards said bottom surface.

28. A capped chip, comprising:
a chip having a front surface and a plurality of conductive features exposed at said front surface;
a cap having an inner surface facing said front surface of said chip, an outer surface opposite said inner surface, and a through hole extending from said outer surface to said inner surface; and
a conductive interconnect conductively contacting from one of said conductive features and extending through said through hole, said interconnect including a rod-like conductive article extending from below said inner surface of said cap to a level above said outer surface, said conductive article occupying a substantial portion of a volume of said interconnect, said conductive interconnect including a flowable conductive medium joining said conductive article to one of said plurality of conductive features or to said cap.

29. The capped chip as claimed in claim 28, wherein said conductive article includes a rod-like inner element having at least one of a conductive, nonconductive or semiconductive region and a conductive coating overlying an exterior of said inner element.

30. The capped chip as claimed in claim 28, wherein said conductive article includes at least one material selected from the group consisting of metals, ceramics, glasses and polymers.

31. The capped chip as claimed in claim 28, wherein said conductive article is hollow.

32. The capped chip as claimed in claim 28, wherein said conductive article includes at least one material in form of at least one selected from the group consisting of foam and sponge.

33. The capped chip as claimed in claim 28, wherein said conductive article is compliant, such that said conductive article is operable to yield under pressure applied to a top of said conductive article.

34. The capped chip as claimed in claim 28, wherein said through hole is tapered from a first opening size in said outer surface of said cap to a second opening size in said inner surface smaller than said first opening size and said conductive article has shape in form of a cylinder and a frustum extending outward from a portion of a length of said cylinder.

35. The capped chip as claimed in claim 28, wherein said conductive article has a wettable exterior surface and said flowable conductive medium wets said wettable exterior surface of said conductive article, said flowable conductive medium selected from the group consisting of a fusible conductive medium and a conductive adhesive.

36. A method of forming a capped chip having a plurality of conductive interconnects, comprising:
aligning a cap member having an outer surface defining a major surface of said cap member and an inner surface opposite said outer surface to a chip having a contact-bearing surface and a plurality of contacts exposed at said contact-bearing surface, such that said inner surface of said cap member faces said contact-bearing surface of said chip;
providing a plurality of loose conductive articles in said through holes; and
flowing a conductive material into said through holes to bond said loose conductive articles to said exposed contacts to form said conductive interconnects.

37. A method as claimed in claim 36, wherein said step of flowing said conductive material includes elevating a temperature of said conductive material to a bonding temperature, said loose conductive articles being characterized by an initial shape prior to said step of flowing said conductive material, said loose conductive articles retaining said initial shape when said temperature is elevated to said bonding temperature.

38. A method of forming a capped chip comprising:
(a) providing a chip having a front surface and a plurality of conductive features at said front surface;
(b) assembling a lid having an outer surface, an inner surface opposite said outer surface and a plurality of through holes extending between said inner and outer surfaces, to said chip such that said bottom surface faces said front surface of said chip and said outer surface faces away from said chip, said through holes are aligned with said conductive features of said chip and said bottom surface is vertically spaced from said front surface of said chip;
(c) placing loose conductive articles into said through holes in contact with at least ones of i) said conductive features or ii) said lid; and
(d) forming conductive interconnects having conductive paths extending through at least portions of said conductive interconnects extending from said conductive features at least partially through said through holes,
said forming step including causing a flowable conductive material to flow in said through holes and conductively join said conductive articles to at least one of said plurality of conductive features or to said lid.

39. A method as claimed in claim 38, wherein said flowable conductive material is caused to flow into said through holes from said top surface of said lid to contact said conductive features of said chip.

40. A method as claimed in claim 39, wherein said through holes have walls wettable by said flowable conductive medium, said fiowable conductive material joined to said wettable walls.

41. The capped chip as claimed in claim 28, wherein said conductive article includes at least one material selected from the group consisting of metals, ceramics, glasses and polymers.
